(19) United States
(12) Patent Application Publication
(10) Pub. No.: US 2025/0070748 A1
(43) Pub. Date: Feb. 27, 2025

(54) PIEZOELECTRIC DEVICE

(71) Applicant: KYOCERA CORPORATION, Kyoto-shi, Kyoto (JP)

(72) Inventors: Masaaki OTA, Higashine-shi (JP); Nobutaka ABE, Nishimurayama-gun (JP); Takao KUSUKI, Higashine-shi (JP); Takahiro UETA, Higashine-shi (JP); Masahiko GOTO, Tendo-shi (JP)

(73) Assignee: KYOCERA CORPORATION, Kyoto-shi, Kyoto (JP)

(21) Appl. No.: 18/718,825

(22) PCT Filed: Dec. 23, 2022
(86) PCT No.: PCT/JP2022/047654

§ 371 Date: Jun. 12, 2024

(30) Foreign Application Priority Data
Dec. 28, 2021 (JP) 2021-214106
Dec. 28, 2021 (JP) 2021-214107

(51) Int. Cl. H03H 9/02; G01K 7/18; H03H 9/10; H03H 9/145; H03H 9/19

(52) U.S. Cl. CPC H03H 9/02834; G01K 7/183; H03H 9/1064; H03H 9/145; H03H 9/19

(57) ABSTRACT

A piezoelectric device includes a piezoelectric element, a mount base, and a temperature sensor element. The mount base includes a recess configured to be hermetically sealed. The recess includes a bottom surface on which the piezoelectric element is mounted. The temperature sensor element includes a portion located closer to an upper end of the recess than the piezoelectric element.

### TECHNICAL FIELD

The present disclosure relates to a piezoelectric device.

### BACKGROUND OF INVENTION

Piezoelectric devices such as quartz crystal resonators and quartz crystal oscillators are known (for example, see Patent Literature below). Such a piezoelectric device includes a piezoelectric element and a package holding the piezoelectric element. The piezoelectric element includes a piezoelectric material (for example, a quartz crystal blank), two excitation electrodes stacked on the piezoelectric material, and two extension electrodes extended from the two excitation electrodes. The two extension electrodes, for example, are joined to pads of the package with a conductive joining material, thus contributing to mounting the piezoelectric element onto the package.

As such a piezoelectric device, one having a temperature sensor element such as a thermistor is known. The temperature detected by the temperature sensor element is used, for example, to compensate for characteristic changes of the piezoelectric element caused by temperature changes.

The temperature sensor element is mounted on or in a package. For example, in Patent Literature 1, a package includes a first recess and a second recess open on the side opposite to the first recess. A piezoelectric element is housed in the first recess and mounted on a bottom surface of the first recess. The first recess is closed and hermetically sealed by a lid. The temperature sensor element is a chip component and is housed in the second recess and mounted on a bottom surface of the second recess. Specifically, two terminals of the temperature sensor element are joined to two pads located on the bottom surface of the second recess with a conductive joining material.

### CITATION LIST

### Patent Literature

Patent Literature 1: Japanese Unexamined Patent Application Publication No. 2011-211340

### SUMMARY

In a configuration of the present disclosure, a piezoelectric device includes a piezoelectric element, a mount base, and a temperature sensor element. The mount base includes a recess configured to be hermetically sealed. The recess includes a bottom surface on which the piezoelectric element is mounted. The temperature sensor element includes a portion located closer to an upper end of the recess than the piezoelectric element.

### BRIEF DESCRIPTION OF THE DRAWINGS

FIG. 1 is an exploded perspective view of a quartz crystal vibrator according to a first embodiment.

FIG. 2 is another exploded perspective view of the quartz crystal resonator in FIG. 1.

FIG. 3 is a cross-sectional view taken along line III-III in FIG. 1.

FIG. 4A is a plan view of another example of outer electrodes of a temperature sensor element.

FIG. 4B is a plan view of still another example of outer electrodes of a temperature sensor element.

FIG. 5A is a cross-sectional view of another example of the position of a temperature sensor element.

FIG. 5B is a cross-sectional view of still another example of the position of a temperature sensor element.

FIG. 5C is a cross-sectional view of still another example of the position of a temperature sensor element.

FIG. 6 is a perspective view of another example of the shape of a temperature sensor element.

FIG. 7 is a cross-sectional view of a quartz crystal resonator according to a second embodiment.

FIG. 8 is a cross-sectional view of a quartz crystal resonator according to a third embodiment.

FIG. 9 is an exploded perspective view of a quartz crystal resonator according to a fourth embodiment.

FIG. 10 is another exploded perspective view of the quartz crystal resonator in FIG. 9.

FIG. 11 is a cross-sectional view taken along line XI-XI in FIG. 9.

FIG. 12A is a plan view of another example of element terminals of a temperature sensor element.

FIG. 12B is a plan view of still another example of element terminals of a temperature sensor element.

FIG. 13 is a plan view of still another example of element terminals of a temperature sensor element.

FIG. 14A is a cross-sectional view of another example of the shape of a temperature sensor element.

FIG. 14B is a cross-sectional view of still another example of the shape of a temperature sensor element.

FIG. 15A is a cross-sectional view of another example of fixation of a temperature sensor element to a mount base.

FIG. 15B is a cross-sectional view of still another example of fixation of a temperature sensor element to a mount base.

FIG. 15C is a cross-sectional view of still another example of fixation of a temperature sensor element to a mount base.

FIG. 16 is a perspective view of a specific example of wiring in a package.

FIG. 17 is a perspective view of another specific example of wiring in a package.

FIG. 18 is a plan view of still another specific example of wiring in a package.

FIG. 19 is a schematic diagram illustrating an application example of a quartz crystal resonator according to the embodiments.

### DESCRIPTION OF EMBODIMENTS

Hereinafter, embodiments according to the present disclosure will be described with reference to the drawings. The figures used in the following description are schematic. Hence, for example, the ratios of dimensions and the like on the drawings are not necessarily the same as those of an actual one. The ratios of dimensions of the same members are also not consistent between the drawings. In addition, illustration of details are sometimes omitted, and illustration of some shapes are sometimes exaggerated. However, this explanation is not intended to deny that the ratios of actual dimensions may be the same as those in the drawings and that features of shapes, the ratios of dimensions, and the like may be extracted from the drawings.

Some drawings include a Cartesian coordinate system D1-D2-D3 for convenience. As for the piezoelectric devices according to the embodiments, any direction may be a vertical direction or a horizontal direction. However, a +D3 direction is sometimes expressed as an upward direction, for convenience. Plan view or transparent plan view denotes viewing parallel to a D3 direction, unless otherwise noted.

In the description of configurations (embodiments and other examples) described relatively later, basically, only differences from configurations described earlier will be described. Items not specifically referred to may be considered to be the same as or similar to those in the configurations described earlier or may be inferred from those in the configurations described earlier. Explanation of configurations described earlier may be applied to configurations described later unless a contradiction or the like occurs. Explanation of configurations described later may be applied to configurations described earlier unless a contradiction or the like occurs. In a plurality of configurations, members corresponding to each other are sometimes denoted by the same symbols for convenience, even if they have differences.

Although the term “side” which refers to an edge portion of a planar shape, in general, indicates an edge portion (in other words, a straight line) of a polygon, this term is sometimes used in the description of the embodiments for convenience to refer to an edge portion of a shape that need not be a polygon (for example, an edge portion that may be a curved line). Similarly, although the terms “long side” and “short side”, in general, refer to the sides of a rectangle, these terms are sometimes used in the description of the embodiments for convenience to refer to an edge portion or a portion similar to an edge portion of a shape that need not be a rectangle (that, however, is a shape from which four edge portions can be recognized). Although the term “parallel” typically refers to such a relationship that the distance between straight lines is uniform, this term is sometimes used in the description of the embodiments for convenience to refer to such a relationship that the distance between lines that need not be straight lines (for example, curved lines) is uniform. The term “rectangle” or “rectangular” mentioned herein is not limited to a square in a strict sense or a rectangle in a narrow sense unless otherwise noted and includes those with chamfered corners. The same or a similar explanation applies to polygons other than rectangles.

### Overview of Embodiments

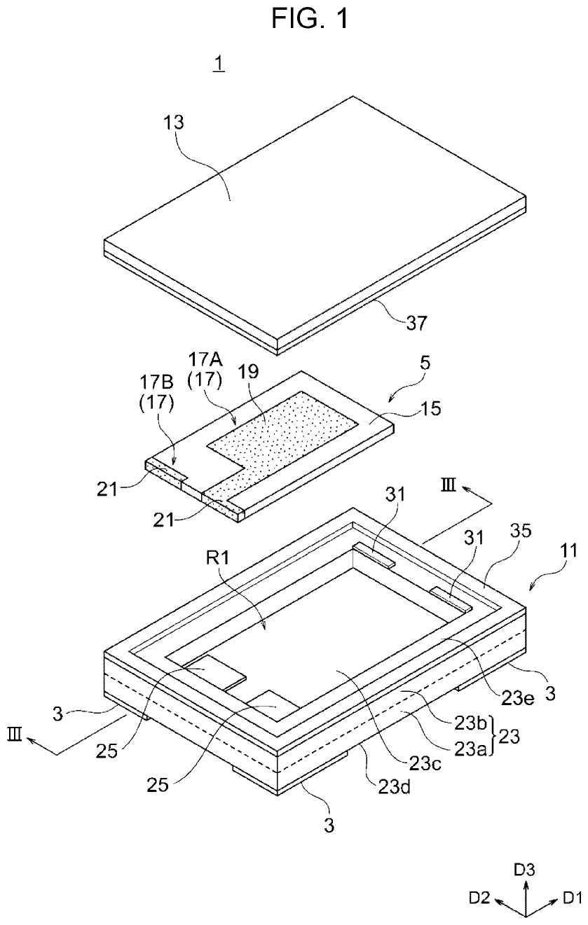

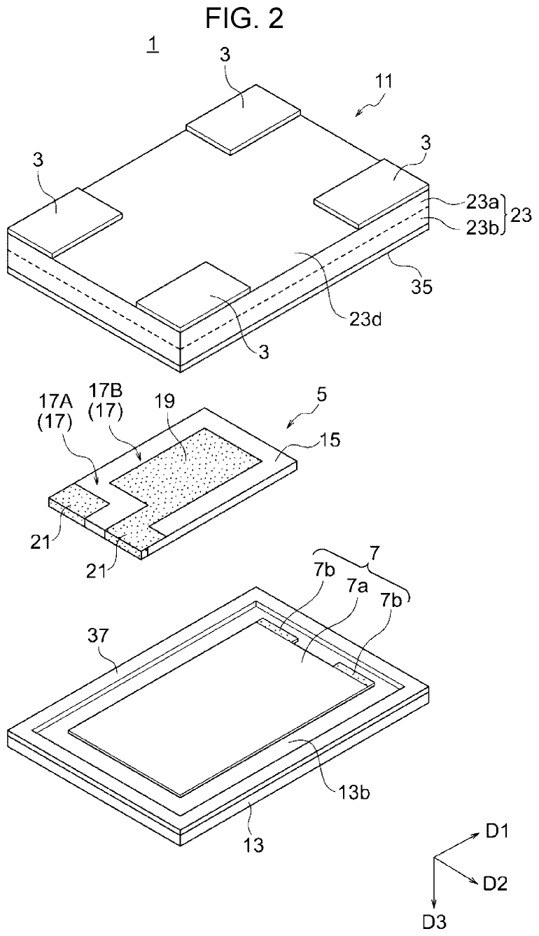

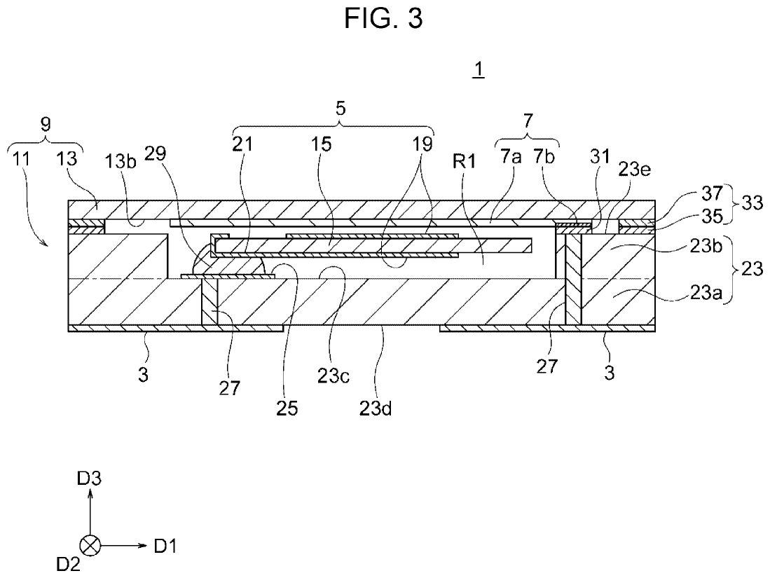

FIG. 1 is an exploded perspective view of a quartz crystal resonator 1 (in the following, the words “quats crystal” are sometimes omitted) according to an embodiment (to be more specific, a first embodiment), illustrating its configuration. FIG. 2 is an exploded perspective view of the quartz crystal resonator 1 from the side opposite to the view in FIG. 1. FIG. 3 is a cross-sectional view taken along line III-III in FIG. 1.

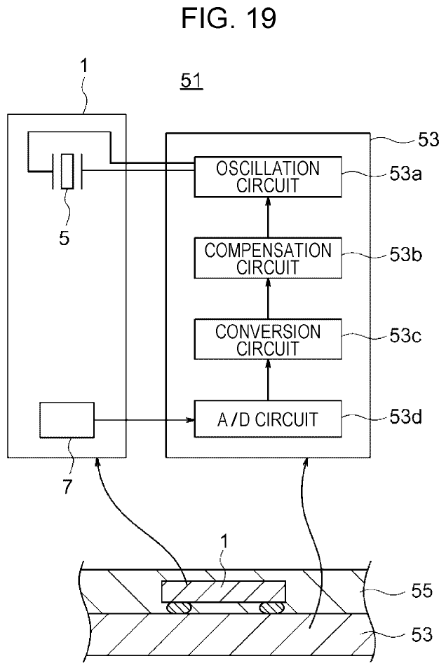

The vibrator 1 is, for example, a chip electronic component configured to be surface-mounted. Specifically, the shape of the vibrator 1 is approximately a thin rectangular parallelepiped as a whole (a shape the dimension of which in the D3 direction is smaller than those in a D1 direction and a D2 direction). A lower surface of the rectangular parallelepiped has layer-shaped four terminals 3 at its four corners. The four terminals 3 are joined to pads (not illustrated) of a circuit substrate 53 (see FIG. 19 described later) with a conductive joining material (for example, solder), and thereby the vibrator 1 is fixed to and also electrically connected to (in other words, mounted on) the circuit substrate 53.

The vibrator 1 includes a quartz crystal element 5, a temperature sensor element 7 (FIGS. 2 and 3), and a package 9 (the symbol of which is in FIG. 3) holding these elements (5 and 7). The quartz crystal element 5 vibrates when an alternate current voltage is applied, for example, through two of the four terminals 3. This vibration is used, for example, to generate an oscillation signal the strength (for example, voltage or current) of which oscillates at a constant frequency. The frequency of the oscillation signal is not particularly limited. The temperature sensor element 7 outputs a signal according to temperature through the other two of the four terminals 3. This signal is used, for example, to compensate for characteristic changes of the quartz crystal element 5 caused by temperature changes.

The package 9 serves as an outer case of the vibrator 1 and has the aforementioned terminals 3. The package 9 includes, for example, a mount base 11 including a recess R1 and includes a lid 13 configured to close the recess R1. The quartz crystal element 5 is housed in the recess R1. An upper opening of the recess R1 is closed by the lid 13 to form a closed space (hermetically sealed space) with the quartz crystal element 5 inside. The closed space is under vacuum or filled with an appropriate gas (for example, nitrogen). The mount base 11 has the aforementioned four terminals 3 on its lower surface. The quartz crystal element 5 is mounted on a bottom surface of the recess R1. With this, the quartz crystal element 5 is electrically connected to two terminals 3.

The temperature sensor element 7 includes a portion located between the quartz crystal element 5 and the lid 13. In other words, the temperature sensor element 7 includes a portion located closer to the upper end of the recess R1 than the quartz crystal element 5. Specifically, in the illustrated example, the temperature sensor element 7 is a film element (for example, a thin film thermistor) stacked on the lower surface of the lid 13 (a lid lower surface 13b), and thus, the temperature sensor element 7 is located between the quartz crystal element 5 and the lid 13. Electrical connection between the temperature sensor element 7 and two terminals 3 is achieved by, for example, connecting the temperature sensor element 7 and the mount base 11 on the periphery of the upper opening of the recess R1.

The package 9 is mounted on the circuit substrate 53 (FIG. 19) with the terminals 3 located on its lower surface. Hence, heat from other devices mounted on the circuit substrate 53 is likely to be transmitted via the circuit substrate 53 to the package 9 through its lower surface. Hence, for example, if the temperature sensor element 7 is located closer to the bottom surface of the recess R1 than the quartz crystal element 5 or located on the lower surface of the package 9, the measured temperature can be excessively affected by external heat, and the measured temperature can deviate from the temperature of the quartz crystal element 5. The present embodiment in which the temperature sensor element 7 is located closer to the lid 13 than the quartz crystal element 5 reduces the probability of occurrence of the situation mentioned above.

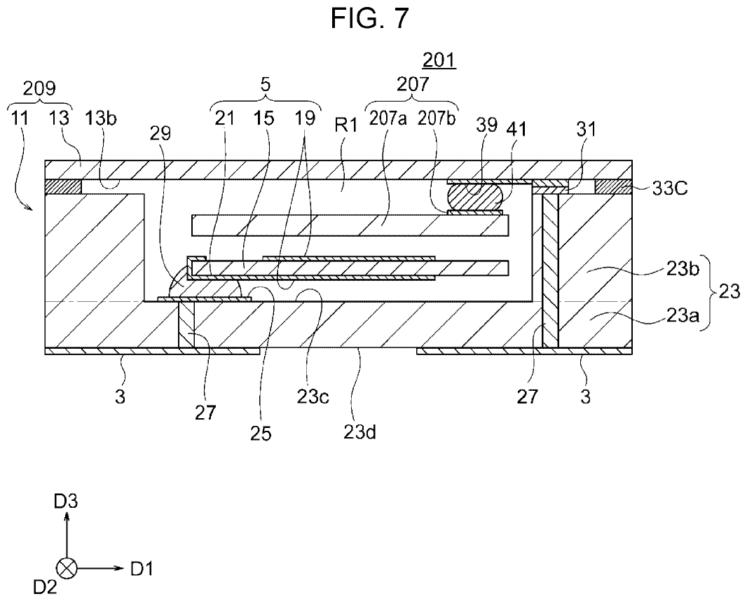

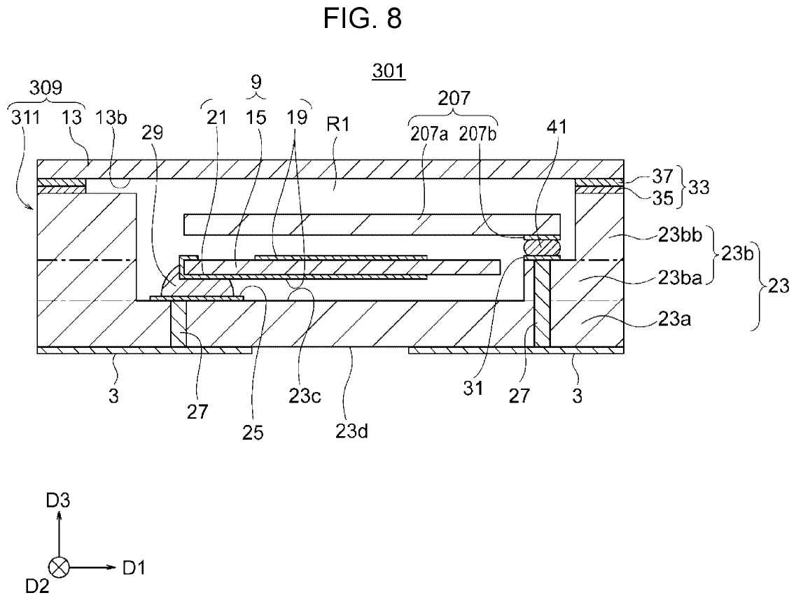

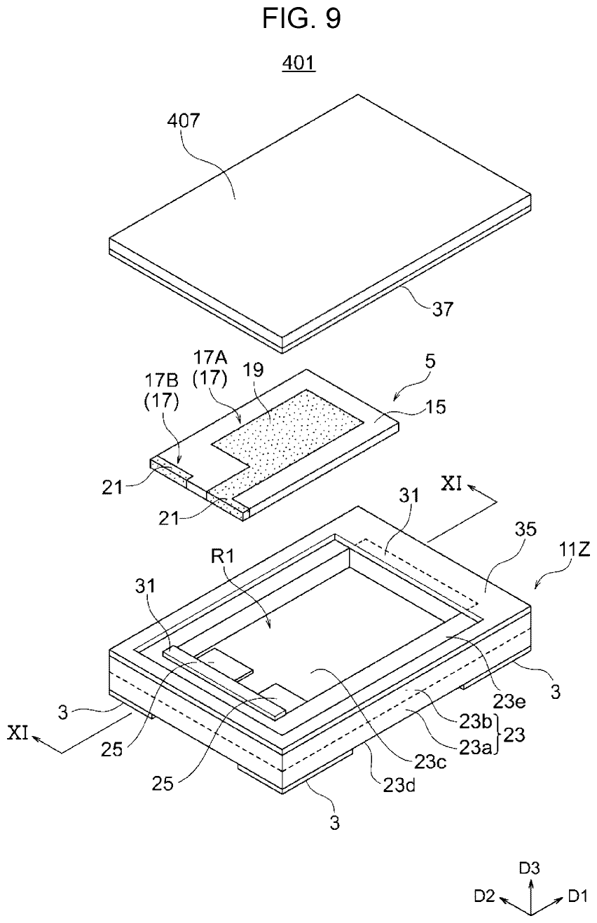

In any of the following first to fourth embodiments, the temperature sensor element (7 or the like) includes a portion located closer to the upper end of the recess R1 than the quartz crystal element 5 as described above. In the first embodiment, the temperature sensor element 7 is a film element stacked on the lower surface of the lid 13 as described with reference to FIGS. 1 to 3. In the second to fourth embodiments (FIGS. 7, 8, and 9), a temperature sensor element 207 or 407 is a chip type element. In the second embodiment (FIG. 7), the temperature sensor element 207 is mounted on the lower surface of the lid 13. In the third embodiment (FIG. 8), the temperature sensor element 207 is mounted at a wall portion of the recess R1. In the fourth embodiment (FIG. 9), the temperature sensor element 407 serves as a lid for hermetically sealing the recess R1.

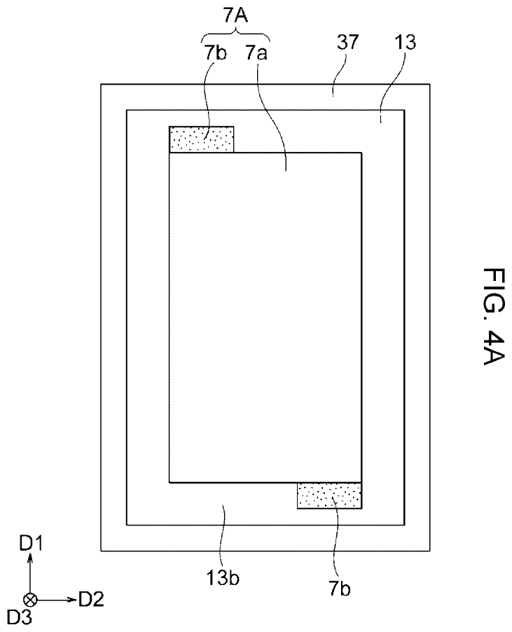

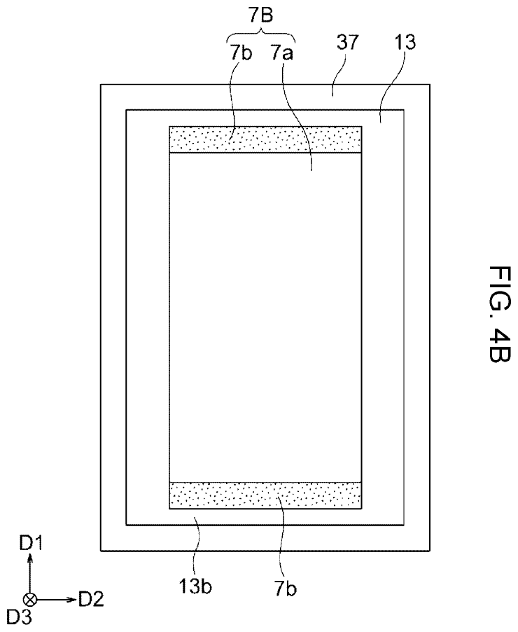

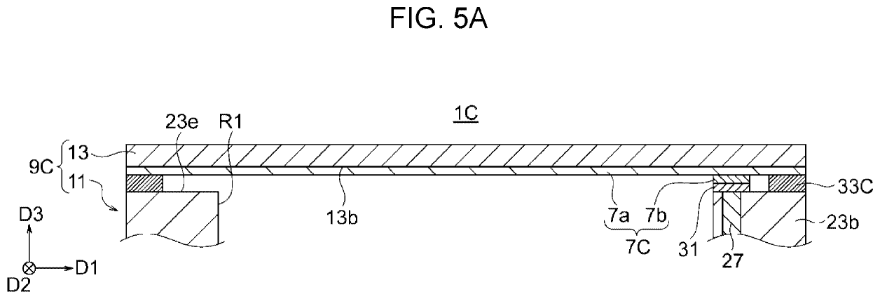

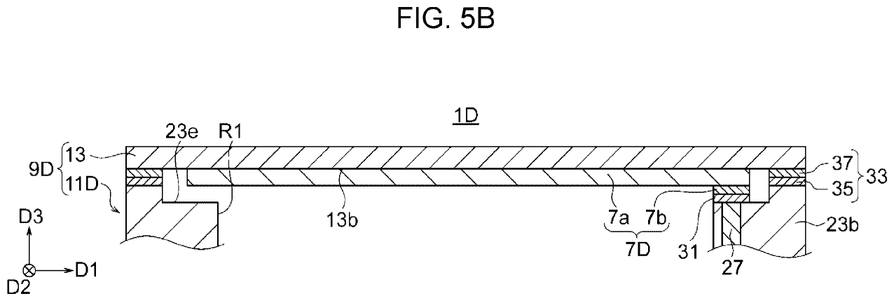

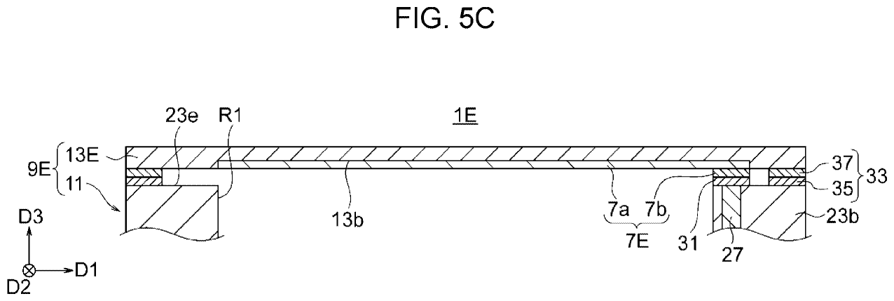

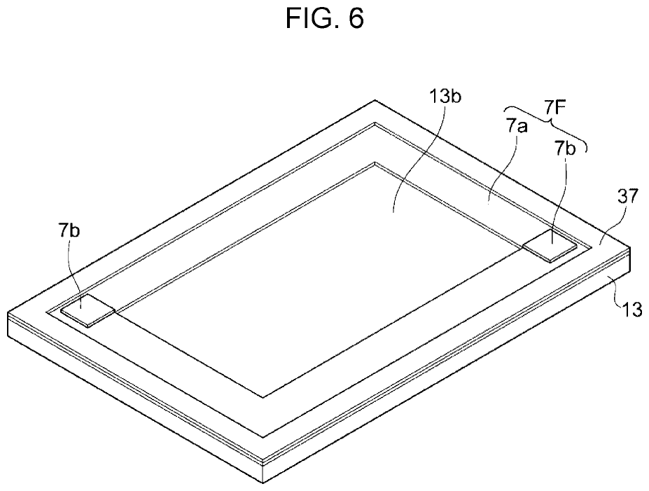

The above is an overview of the vibrator (1 or the like) according to the embodiments. In the following, description will be made on the vibrator nearly in the following order.
1. First Embodiment
   1.1. Quartz Crystal Element
   1.2. Package (Excluding Portions Related to Temperature Sensor Element)
      1.2.1. Insulation Base
      1.2.2. Conductors in Mount Base (Excluding Portions Related to Joining between Mount Base and Lid)
      1.2.3. Joining Material
      1.2.4. Lid
      1.2.5. Joining between Mount Base and Lid
   1.3. Temperature Sensor Element (Including Portions of Package Related to Temperature Sensor Element)
      1.3.1. Overview of Configuration of Temperature Sensor Element
      1.3.2. Correspondence Relationship between Constituents of Temperature Sensor Element and Those in Drawings
      1.3.3. Position, Shape, and Dimensions of Temperature Sensor Element
      1.3.4. Positions, Shapes, and Dimensions of Outer Electrodes
      1.3.5. Portions of Package Related to Temperature Sensor Element
   1.4. Other Examples according to First Embodiment
      1.4.1. Other Examples of Outer Electrodes (FIGS. 4A and 4B)
      1.4.2. Other Examples of Temperature Sensor Film (FIGS. 5A to 5C and 6)
   1.5. Summary of First Embodiment
2. Second Embodiment
3. Third Embodiment
4. Fourth Embodiment
   4.1. Quartz Crystal Resonator
   4.2. Other Examples according to Fourth Embodiment
      4.2.1. Other Examples of Connection Electrodes
      4.2.2. Other Examples of Element Body
   4.3. Summary of Fourth Embodiment
5. Specific Example of Wiring in Package
6. Application Example of Quartz Crystal Resonator

### 1. First Embodiment

### 1.1. Quartz Crystal Element

The quartz crystal element 5 includes, for example, a quartz crystal blank 15 (in other words, a piezoelectric material) and two or more (in the illustrated example, a pair of) conductor patterns 17 (two in the illustrated example, a first conductor pattern 17A and a second conductor pattern 17B) stacked on the quartz crystal blank 15. When a voltage is applied to the quartz crystal blank 15 through the pair of conductor patterns 17, the quartz crystal blank 15 vibrates. This causes the quartz crystal element 5 to provide the aforementioned function. The quartz crystal element 5 may have various specific configurations. For example, the quartz crystal element 5 may have various publicly-known configurations.

Note that in a configuration in which when the quartz crystal blank 15 is fabricated by etching, the quartz crystal blank 15 includes inclined surfaces (in another viewpoint, crystal surfaces) on side surfaces or the like in some cases due to the anisotropy of quartz crystal in etching. In the description of the embodiments, the presence of such inclined surfaces are not taken into account. When strictness is required in explanation of dimensions and the like, the explanation may be construed without inclined surfaces taken into account or with inclined surfaces taken into account unless it is unreasonable or a contradiction occurs. For example, when the length of the quartz crystal blank 15 in the D1 direction is referred to, the length may be the length of an upper surface or a lower surface (the length excluding crystal surfaces) of the quartz crystal blank 15 or may be the maximum length in transparent plan view (the length with crystal surfaces taken into account).

In the illustrated example, the quartz crystal element 5 is a so-called AT-cut quartz crystal element. In the AT-cut quartz crystal element 5, the quartz crystal blank 15 has approximately a plate shape. The pair of conductor patterns 17 includes a pair of excitation electrodes 19 stacked on both main surfaces (the largest surfaces of the plate shape, the front and back sides of the plate shape) of the plate-shaped quartz crystal blank 15 and a pair of extension electrodes 21 extended from the pair of excitation electrodes 19.

The pair of excitation electrodes 19 contributes to applying a voltage to the quartz crystal blank 15. When an alternate current voltage is applied to the AT-cut quartz crystal blank 15, so-called thickness-shear vibration occurs. The pair of extension electrodes 21 contributes to mounting the quartz crystal element 5. More specifically, in the illustrated example, the pair of extension electrodes 21 is joined to a pair of pads 25 described later with a pair of pieces of joining material 29 (FIG. 3), and thereby the quartz crystal element 5 is electrically connected and also fixed to the package 9 and is supported in a manner of a cantilever.

Examples of quartz crystal elements other than the illustrated example include the following: a tuning fork-shaped element that uses bending vibration, a CT-cut or DT-cut element that uses contour-shear vibration, an element that uses thickness-shear vibration and the cut-angle of which is other than AT-cut (for example, BT-cut), and an element using a surface acoustic wave (SAW). Note that also such elements include, for example, a piezoelectric material (for example, quartz crystal), two or more excitation electrodes that excite the piezoelectric material, and two or more extension electrodes extended from the two or more excitation electrodes. In an element using SAW, the layer of a piezoelectric material may be stacked on a layer of a different material.

Note that the description of the present embodiments is sometimes expressed for convenience without a notation on the assumption that the quartz crystal element 5 is of an AT-cut type.

In the quartz crystal element 5 (which is not limited to ones of an AT-cut type) including the plate-shaped quartz crystal blank 15, the pair of excitation electrodes 19 stacked on both main surfaces of the quartz crystal blank 15, and the pair of extension electrodes 21 extended from the pair of excitation electrodes 19 as in the illustrated example, more specific configurations (such as planar shapes) of the quartz crystal blank 15, the excitation electrodes 19, and the extension electrodes 21 may be determined as appropriate.

For example, the shapes of the quartz crystal blank 15, the excitation electrodes 19, and the extension electrodes 21 may have a configuration in which any of both sides of the quartz crystal element 5 can be the joining side (on a −D3 side) or may have a different configuration (the illustrated example) from such a configuration. For example, the quartz crystal element 5 may be approximately 180-degree rotationally symmetric with respect to the center line (not illustrated) extending in the D1 direction (in the illustrated example, in a longitudinal direction of the quartz crystal element 5) or may have a different configuration (the illustrated example) from such a configuration.

For example, the planar shape of the quartz crystal blank 15 may be rectangular (the illustrated example), circular, elliptical, or a polygon other than rectangles. In addition, the planar shape of the quartz crystal blank 15 may be one formed by bulging any number of sides of a polygon (for example, one side, two sides, three sides, or the four sides of a rectangular shape) outward into curved lines. The planar shape of the quartz crystal blank 15 may be one including a protrusion or a cutout in some portion. For example, the planar shape of the quartz crystal blank 15 may be one the longitudinal direction of which is parallel to the D1 direction (a shape in which the maximum length in the D1 direction is longer than the maximum length in the D2 direction) or may be such a shape that such distinguishing cannot be made.

For example, the thickness of the quartz crystal blank 15 may be uniform (the illustrated example) or nonuniform. Although not illustrated, examples of the latter include the following: a so-called mesa type in which the center region (mesa portion) overlapping a pair of excitation electrodes 19 and configured to be excited is thicker than the regions around it, a so-called inverted-mesa type in which contrary to the above, the center region (inverted-mesa portion) overlapping a pair of excitation electrodes 19 and configured to be excited is thinner than the regions around it, one including a vibration portion overlapping the pair of excitation electrodes 19 and configured to be excited and a fixation portion that is adjacent to part (for example, one side, two sides, or three sides) of the edge portions of the vibration portion and thicker than the vibration portion and on which a pair of extension electrodes 21 are located, and a bevel type in which the thickness of an outer peripheral portion decreases toward an outer peripheral edge.

For example, the planar shapes of the excitation electrodes 19 may be similar to the planar shape of the quartz crystal blank 15 (the illustrated example) (or the planar shape of the mesa portion, the inverted-mesa portion, or the vibration portion mentioned above (the same or a similar explanation applies in this paragraph)) or may be different shapes. Examples of the former include configurations in which the planar shape of the quartz crystal blank 15 and the planar shapes of the excitation electrodes 19 are rectangular-rectangular, circular-circular, and elliptical-elliptical. Examples of the latter include configurations in which the planar shape of the quartz crystal blank 15 and the planar shapes of the excitation electrodes 19 are rectangular-circular, rectangular-elliptical, and elliptical-rectangular. Whether the planar shapes of the excitation electrodes 19 are similar to the planar shape of the quartz crystal blank 15 or not, the explanation above about the planar shape of the quartz crystal blank 15 may be applied to the planar shapes of the excitation electrodes 19 unless a contradiction or the like occurs.

For example, the pair of extension electrodes 21 are extended from the excitation electrodes 19 to one end side of the quartz crystal blank 15. More specifically, for example, as already touched on, each extension electrode 21 includes a wiring portion extending from the corresponding excitation electrode 19 and a pad-shaped terminal portion connected to the excitation electrode 19 with the wiring portion interposed therebetween, although symbols are not attached. The terminal portions are configured to be joined to the pads 25.

In the quartz crystal element 5 that uses thickness-shear vibration, the thickness of the quartz crystal blank 15 (which refers to the thickness of the portion on which the excitation electrodes 19 are stacked in this paragraph unless otherwise noted) is a factor that determines the frequency of the oscillation signal. As is known, for example, for an AT-cut quartz crystal element, basically the relationship f=1.67×n/t holds, where f is frequency (MHz), n is the order of vibration in use, and t (mm) is thickness. The quartz crystal element 5 may be one using the fundamental wave mode or one using an overtone mode. As already mentioned, the frequency of the oscillation signal is not particularly limited, and thus, also the thickness of the quartz crystal blank 15 is not particularly limited. For example, the thickness of the quartz crystal blank 15 may be 5 μm or more, 10 μm or more, 30 μm or more, or 50 μm or more and may be 200 μm or less, 100 μm or less, 50 μm or less, or 30 μm or less. Any lower and upper limits mentioned above may be combined so as not to make a contradiction.

As can be understood from the explanation above, the maximum thickness of the AT-cut quartz crystal blank 15 may be the same as or different from the thickness that defines the aforementioned frequency. In any way, the maximum thickness of the quartz crystal blank 15 is not particularly limited. The maximum thickness of a quartz crystal blank (or a quartz crystal element) of an AT-cut type or other types may be, for example, 30 μm or more, 50 μm or more, or 100 μm or more and may be 300 μm or less, 200 μm or less, 100 μm or less, or 50 μm or less. Any lower and upper limits mentioned above may be combined so as not to make a contradiction.

The material of the conductor patterns 17 may be, for example, a metal. Examples of the metal include nickel (Ni), chromium (Cr), titanium (Ti), gold (Au), and silver (Ag) and an alloy containing at least one of these as a main component. Each conductor pattern 17 may be one conductor layer composed of a single material or may be a laminate consisting of a plurality of conductor layers composed of materials different from one another. The conductor patterns 17, for example, may be composed of the same material over the entire area or may be composed of different materials depending on the region.

### 1.2. Package (Excluding Portions Related to Temperature Sensor Element)

The package 9 serves as the outer case of the vibrator 1, and its outer shape is approximately a thin rectangular parallelepiped. The dimensions of the package 9 (vibrator 1) are not particularly limited. In an example of a case in which the vibrator 1 is relatively small, the length in a longitudinal direction or a lateral direction (the D1 direction or the D2 direction) in plan view is 0.6 mm or more and 2.0 mm or less. The thickness (the length in the D3 direction) is 0.2 mm or more and 1.5 mm or less.

As already mentioned, the package 9 includes the mount base 11 and the lid 13. The mount base 11 includes, for example, an insulation base 23 and various conductors located on or in the insulation base 23. The various conductors include, for example, the aforementioned terminals 3, the two pads 25 (FIGS. 1 and 3) on which the quartz crystal element 5 is mounted, and a plurality of pieces of wiring 27 (FIG. 3) contributing to electrical connection within the package 9. The plurality of pieces of wiring 27 includes, for example, two pieces of wiring 27 connecting the two pads 25 and two terminals 3.

### 1.2.1. Insulation Base

The shape, dimensions, and material of the insulation base 23 are not particularly limited. The insulation base 23 includes most part of the mount base 11, and the outer shape (the shape without the recess R1 taken into account) is approximately a thin rectangular parallelepiped. The recess R1 is open in the upper face of the insulation base 23 (the face on a +D3 side). Although not illustrated, each corner of the insulation base 23 may be chamfered or rounded or may have a recess (castellation) in plan view.

Since the insulation base 23 includes the recess R1, the insulation base 23 may be considered to include a substrate portion 23a including the bottom surface of the recess R1 and a frame portion 23b including wall portions of the recess R1. Note that the insulation base 23 may be fabricated by stacking the substrate portion 23a and the frame portion 23b or may be fabricated by a manufacturing method different from such a manufacturing method. Examples of the former include a method in which an opening serving as the recess R1 is formed in a ceramic green sheet having one layer (or two or more layers) serving as the frame portion 23b, and the ceramic green sheet having the opening and a ceramic green sheet having one layer (or two or more layers) serving as the substrate portion 23a are stacked and fired. Examples of the latter include a method in which the recess R1 is formed in a ceramic green sheet having one layer (or two or more layers) by press working, and the resultant sheet is fired. As can be understood from the latter manufacturing method, the substrate portion 23a and the frame portion 23b (in another viewpoint, insulation layers different from each other) may be portions for the sake of convenience that are recognized according to the shape of the insulation base 23 and/or the conductor layers in the insulation base 23.

The substrate portion 23a is, for example, approximately flat plate-shaped. In other words, the substrate portion 23a includes a first substrate surface 23c and a second substrate surface 23d on the opposite side, and both are flat surfaces parallel to each other. The first substrate surface 23c serves as the bottom surface of the recess R1. The second substrate surface 23d serves as the lower surface of the package 9. The planar shape of the substrate portion 23a is, for example, rectangular because the outer shape of the insulation base 23 is a rectangular parallelepiped. In other words, the substrate portion 23a in plan view includes a pair of long sides opposed to each other and a pair of short sides opposed to each other. Note that the ratio of the lengths of the long side and the short side is not particularly limited. Also the thickness of the substrate portion 23a is not particularly limited.

The frame portion 23b extends, for example, along the edge portions of an upper surface of the substrate portion 23a. The shape of the outer edges of the frame portion 23b in plan view is, for example, approximately the same as the shape of the outer edges of the substrate portion 23a. The shape of the inner edges of the frame portion 23b (the shape of the recess R1 in plan view) is, for example, a rectangular shape having four sides approximately parallel to the four sides of the outer edges of the frame portion 23b. The frame portion 23b has, for example, a uniform thickness. The outer peripheral surfaces and the inner peripheral surfaces of the frame portion 23b are, for example, approximately parallel to the D3 direction. However, unlike the illustrated example, for example, the inner peripheral surfaces of the frame portion 23b may be inclined such that the length of the recess R1 in D1 and/or D2 directions increases toward the upper side (the +D3 side). Note that whether such an inclination is present or not, the shape and dimensions of the recess R1 in plan view referred to in the description of the embodiment may refer to those of the opening of the upper face of the recess R1 (the inner edges of an upper surface of the frame portion 23b (a frame-portion upper surface 23e)) or may refer to those of the bottom surface of the recess R1, unless otherwise noted, and unless a contradiction or the like occurs.

The thickness of the frame portion 23b (the depth of the recess R1) may be determined as appropriate, for example, according to the thickness of the quartz crystal element 5 and the temperature sensor element 7 and the like. For example, the depth of the recess R1 (or the height from the first substrate surface 23c to the lid lower surface 13b (the same explanation applies below in this paragraph)) may be 1.2 times or more, 1.5 times or more, 2 times or more, or 3 times or more and 10 times or less, 5 times or less, 3 times or less, or 2 times or less the total thickness of the quartz crystal element 5 and the temperature sensor element 7 (which does not include the distance between the two elements and which, when the thickness is not uniform, is the maximum thickness, for example). Any lower and upper limits mentioned above may be combined so as not to make a contradiction. The lower limits and/or upper limits mentioned above may be applied to the depth of the recess R1 relative to the thickness of the quartz crystal element 5 alone.

The width (the length from the inner peripheral surface to the outer peripheral surface) of the frame portion 23b is not particularly limited. In the present embodiment, connection electrodes 31 (FIGS. 1 and 3) configured to be electrically connected to the temperature sensor element 7 are provided on the upper surface of the frame portion 23b (the frame-portion upper surface 23e) as described in detail later. Accordingly, the width of the frame portion 23b (and/or the frame-portion upper surface 23e) may be larger than those of conventional packages. Alternatively, this width may be the same as and/or similar to those of conventional ones. In this case, for example, the region for locating the connection electrodes 31 may be ensured on the frame-portion upper surface 23e by making the width of a sealing material 33 (the symbol of which is in FIG. 3) stacked on the frame-portion upper surface 23e smaller than those of conventional ones.

The width of the frame portion 23b and/or the frame-portion upper surface 23e (when the width is not uniform, the maximum width or the width of the side where the connection electrodes 31 are located) may be, for example, 1/20 or more, 1/10 or more, or ⅕ or more and ⅓ or less, ¼ or less, or ⅕ or less of the length of the substrate portion 23a in the longitudinal direction or the lateral direction. Any lower and upper limits mentioned above may be combined so as not to make a contradiction.

The size of the recess R1 in plan view may be determined as appropriate, for example, in consideration of the size of the quartz crystal element 5 in plan view. The size of the temperature sensor element 7 in plan view may be taken into account as necessary. For example, in plan view, the length of the recess R1 in the longitudinal direction (the D1 direction) (when it varies depending on the position or the like in the height direction, for example, the maximum length) may be 1.05 times or more, 1.1 times or more, 1.2 times or more, or 1.5 times or more and 2 times or less, 1.5 times or less, or 1.3 times or less the length (for example, the maximum length) of the quartz crystal element 5 in the longitudinal direction. Any lower and upper limits mentioned above may be combined so as not to make a contradiction.

Note that unlike the illustrated example, the shape of the recess R1 in plan view is not limited to a rectangular shape. In another viewpoint, the inner edges and outer edges of the frame-portion upper surface 23e need not be parallel. For example, assume a configuration in which a quartz crystal element has an arm for vibration or an arm for mounting. In this case, the frame-portion upper surface 23e in plan view may have a protrusion that is inserted between the arm and the other portion of the quartz crystal element. Such a protrusion, for example, can contribute to allocating a region for the connection electrodes 31 configured to be connected to the temperature sensor element 7.

The material of the insulation base 23 (the substrate portion 23a and the frame portion 23b) is not particularly limited and may be, for example, a ceramic. The specific kind of the ceramic is not particularly limited, and examples include aluminum oxide (alumina, Al₂O₃), aluminum nitride (AlN), and low temperature co-fired ceramics (LTCC). As a matter of course, the material of the insulation base 23 may be one other than ceramic or may be a composite material containing a plurality of kinds of material.

### 1.2.2. Conductor in Mount Base (Excluding Portions Related to Joining Between Mount Base and Lid)

As already mentioned, the mount base 11 includes the four terminals 3, the two pads 25, and the wiring 27.

The four terminals 3 are composed of, for example, layer-shaped (pad-shaped) conductors (for example, a metal) stacked on the second substrate surface 23d of the substrate portion 23a. The positions, shapes, and dimensions of the terminals 3 are not particularly limited. For example, the four terminals 3 are located at the four corners of the second substrate surface 23d. Note that in the above explanation, in plan view, each terminal 3 may be away from two edge portions (a long side and a short side) of the second substrate surface 23d intersecting each other, or a configuration in which each terminal 3 is not away from two edge portions (the illustrated example) is possible. Whether the terminals 3 are located at the four corners or not may be judged rationally according to the dimensions of the substrate portion 23a, the dimensions of each terminal 3, the distance between the edge portions of the terminals 3 and the edge portions of the substrate portion 23a, and the like. The same or a similar explanation applies to the pads 25 and the like described later.

The positional relationship between the two terminals 3 connected to the quartz crystal element 5 and the two terminals 3 connected to the temperature sensor element 7 is not particularly limited. For example, the former two terminals 3 may be located on one side (a −D1 side) of the substrate portion 23a in the longitudinal direction, and the latter two terminals 3 may be located on the other side (a +D1 side) of the substrate portion 23a in the longitudinal direction. Alternatively, for example, the former two terminals 3 may be located at one pair of diagonal corners, and the latter two terminals 3 may be located at the other pair of diagonal corners.

The two pads 25 are composed of, for example, a conductive material (for example, a metal) in the form of a layer (in the form of a pad) stacked on the first substrate surface 23c of the substrate portion 23a. The positions, shapes, and dimensions of the pads 25 are not particularly limited. For example, the two pads 25 are located on one end side (the −D1 side) of the center of the substrate portion 23a in the longitudinal direction of the substrate portion 23a and side by side in the lateral direction of the substrate portion 23a. More specifically, the two pads 25 are located at the two corners located on one side in the longitudinal direction out of the four corners of the bottom surface of the recess R1.

The plurality of pieces of wiring 27 may have an appropriate configuration. For example, each piece of wiring 27 may include one of the following: a via conductor extending through the insulation base 23 (the substrate portion 23a and/or the frame portion 23b) in a thickness direction (the D3 direction), a layer-shaped conductor (layer-shaped wiring) stacked on a surface (an upper surface, a lower surface, and/or side surfaces) of the insulation base 23 (the substrate portion 23a and/or the frame portion 23b), and a layer-shaped conductor located inside the insulation base 23 (for example, a boundary between the substrate portion 23a and the frame portion 23b) and extending along (for example, parallel to) a D1-D2 plane (the first substrate surface 23c). Note that a layer-shaped conductor stacked on a side surface of the insulation base 23 includes one located on an inner surface of a castellation (recess).

A piece of wiring 27, illustrated in FIG. 3 as an example, connecting a pad 25 and a terminal 3 includes only a via conductor extending through the substrate portion 23a. In a configuration in which both of the two terminals 3 connected to the quartz crystal element 5 (the two pads 25) are located on one side in the longitudinal direction of the substrate portion 23a, a piece of wiring 27 connecting the pad 25 and the terminal 3 that are not illustrated in FIG. 3 may have the same or a similar structure. Whether the two terminals 3 connected to the quartz crystal element 5 are located at a pair of diagonal corners of the substrate portion 23a or not, the two pieces of wiring 27 connected to the quartz crystal element 5 may have a configuration other than the illustrated one.

Note that from the viewpoint of material and the like, in the connecting portions between via conductors and conductor layers (including not only portions of the wiring 27 but also the pads 25, the terminals 3, the connection electrodes 31, and the like), an upper surface or a lower surface of a conductor layer and a lower end surface or an upper end surface of a via conductor may be joined, a via conductor may extend through a conductor layer, or a configuration in which such distinguishing cannot be made is possible. In the following, in any configuration, expression may sometimes be made for convenience on the assumption that a via conductor is joined to the upper surface or the lower surface of a conductor layer.

The conductor layers (the terminals 3, the pads 25, and the wiring 27) may be one conductor layer composed of a single material or may be a laminate consisting of a plurality of conductor layers composed of materials different from one another. The conductor layers may be composed of different materials depending on the region.

The via conductors (wiring 27) may have various specific configurations. For example, the via conductors may be solid (in a form without a cavity inside) (the illustrated example) or may be hollow. The entire via conductors may be composed of the same material or may have a configuration in which the material inside and the material of the outer peripheral surface are different. For example, the via conductors may be in the form of a straight pillar or in the form of a taper or may have a flange at an appropriate position.

The material of the various conductors (the conductor layers, the via conductors, the terminals 3, the pads 25, and the wiring 27) mentioned above may be, for example, a metal. Examples of the metal include nickel (Ni), tungsten (W), copper (Cu), aluminum (Al), gold (Au), silver (Ag), and platinum (Pt) and an alloy containing at least one of these as a main component.

### 1.2.3. Joining Material

The conductive joining material 29 for joining the quartz crystal element 5 and the pads 25 is, for example, a conductive adhesive. Although not illustrated, the conductive adhesive contains an insulating binder and conductive fillers (conductive powder) dispersed in the binder. The binder may be an organic material (for example, a resin, more specifically, a thermosetting resin) or may be an inorganic material. The resin may be, for example, a silicone resin, an epoxy resin, a polyimide resin, or a bismaleimide resin. The material of the conductive fillers may be, for example, a metal. Examples of the metal include aluminum, molybdenum, tungsten, platinum, palladium, silver, titanium, nickel, and iron and an alloy containing one or more of these as a main component.

### 1.2.4. Lid

The shape, dimensions, and material of the lid 13 are not particularly limited as long as the lid 13 is configured to close the recess R1. In the illustrated example, the lid 13 is approximately a flat plate-shaped member. The planar shape of the lid 13 is approximately the same as that of the frame portion 23b, in other words, a rectangular shape. In another viewpoint, the outer edges of the lid 13 extend along (for example, parallel to) the frame portion 23b. In transparent plan view, for example, the entire outer edges of the lid 13 are located outside the inner edges of the frame portion 23b (more specifically, the frame-portion upper surface 23e). In transparent plan view, part or all of the outer edges of the lid 13 may be aligned with the outer edges of the frame portion 23b (the illustrated example) or may be located inside or outside the outer edges of the frame portion 23b. The thickness of the lid 13 (when the thickness is not uniform, for example, the minimum thickness, the average thickness, or the maximum thickness) may be smaller, equivalent to, or larger than the thickness of the quartz crystal element 5 (or the quartz crystal blank 15) (when the thickness is not uniform, for example, the thickness in the region of the excitation electrodes 19, the minimum thickness, or the maximum thickness).

The material of the lid 13 may be a conductive material (for example, a metal), an insulating material, or a combination of these. Examples of the metal include iron, nickel, and cobalt and an alloy (for example, Kovar) containing at least one of these as a main component. Note that the description of the embodiments is sometimes expressed for convenience on the assumption of a configuration in which the material of the lid 13 is a metal. The insulating material may be an inorganic material (for example, a ceramic) or may be an organic material (for example, a resin).

### 1.2.5. Joining Between Mount Base and Lid

The method of joining the mount base 11 (the frame portion 23b) and the lid 13 is not particularly limited as long as the recess R1 can be closed. In the illustrated example, the sealing material 33 (the symbol of which is in FIG. 3) is interposed between the mount base 11 and the lid 13 to join these. More specifically, the illustrated example has a configuration using seam welding. In this configuration, the sealing material 33 includes, for example, a first metal layer 35 stacked on the upper surface of the frame portion 23b and a second metal layer 37 stacked on a lower surface of the conductive lid 13. Then, with the first metal layer 35 and the second metal layer 37 in contact with each other, a voltage and a pressure are applied to the metal layers (in other words, the metal layers are heated and pressed) to weld these metal layers.

Note that part or all of the sealing material 33 may be considered to be part of the mount base 11 or the lid 13. For example, the first metal layer 35 may be considered to be part of the mount base 11. The second metal layer 37 may be considered to be part of the lid 13. The description of the embodiment may sometimes be expressed for convenience mainly on the assumption that the sealing material 33 is a member different from the mount base 11 and the lid 13. However, the sealing material 33 may sometimes be expressed as part of the mount base 11 or the lid 13 (or the temperature sensor element 407 described later) without a notation.

Although not illustrated, the lid 13 (and/or the sealing material 33 (the first metal layer 35 and/or the second metal layer 37) (the same or a similar explanation applies below in this paragraph), when it is conductive, may be connected to a terminal 3 to which a reference electric potential is applied through a piece of wiring 27. The terminal 3 to which the reference electric potential is applied may be, for example, one of the two terminals 3 connected to the temperature sensor element 7. The path connecting the lid 13 and a terminal 3 may share at least part of the path with the path connecting the temperature sensor element 7 and terminals 3. Note that the temperature sensor element 7 is not limited to ones using a reference electric potential. In this case, the conductive lid 13 may be, for example, electrically floated, or a terminal 3 (not illustrated) for the reference electric potential may be added to apply the reference electric potential to the conductive lid 13.

The materials of the first metal layer 35 and the second metal layer 37 are not particularly limited. For example, the material of the second metal layer 37 may be a brazing material, and the material of the first metal layer 35 may be one for improving the wettability of the second metal layer 37. Specific materials in such a configuration are also not particularly limited. For example, the material of the second metal layer 37 may be a silver solder or gold-tin. The material of the first metal layer 35, for example, may have a configuration in which nickel plating and gold plating are sequentially performed on the surface of a layer of tungsten or molybdenum. Note that in a configuration in which a brazing material is used as the material of the second metal layer 37, seam welding in this configuration may be considered to be brazing.

The method of joining the mount base 11 and the lid 13 may be selected from various ones other than those mentioned above.

For example, the sealing material 33 is not limited to a metal (in another viewpoint, a conductive material) and may be an insulating material. Examples of such a material include glass. In other words, glass sealing may be used. Examples of specific kinds of glass include lead-based and lead-free low-melting glass. Examples of lead-free low-melting glass include bismuth-based and tin-based ones. The glass transition temperature of low-melting glass ranges, for example, from 200° C. to 500° C.

Unlike welding and brazing, for example, joining not involving melting may be performed. In another viewpoint, the second metal layer 37 need not be a brazing material. For example, joining between the first metal layer 35 and the second metal layer 37 may be performed by diffusion bonding (in other words, direct metal to metal bonding). More specifically, for example, specified treatments (for example, polishing and/or activation treatment) may be performed on the surfaces of the first metal layer 35 and the second metal layer 37 to be in contact with each other, and these metal layers may be pressed under a temperature condition below their melting points. Heating may be performed, but processes without heating is possible. Unlike seam welding, applying electric current is not indispensable.

For example, in a configuration in which seam welding (or another welding method) is performed, use of a brazing material (the second metal layer 37 in the above explanation) is not essential. For example, a metal lid 13 may be directly welded to the first metal layer 35. Alternatively, the second metal layer 37 may be composed of a material different from the materials (brazing materials) mentioned above as examples.

For example, the method of heating a conductive or insulating sealing material 33 may be selected from various methods other than running electrical current. For example, heating may be performed by placing the vibrator 1 in a furnace, by irradiation with ultrasonic, by irradiation with laser light, or by a combination of some of these.

The shape and dimensions of the sealing material 33 (in another viewpoint, the first metal layer 35 and/or the second metal layer 37 (in the following, the same or a similar explanation applies in this and the next paragraphs unless otherwise noted)) in plan view are determined such that the region where the sealing material 33 overlaps the frame-portion upper surface 23e in transparent plan view is frame-shaped (annular). For example, the sealing material 33 in transparent plan view has a shape and dimensions within the frame-portion upper surface 23e. In the illustrated example, the outer edges of the sealing material 33 (in another viewpoint, the first metal layer 35) are aligned with the outer edges of the frame-portion upper surface 23e. The outer edges of the sealing material 33 (in another viewpoint, the second metal layer 37) are aligned with the outer edges of the lid lower surface 13b. However, part or all the outer edges of the sealing material 33 being aligned with the outer edges of the frame-portion upper surface 23e and/or the lid lower surface 13b is not essential.

As already mentioned, the frame-portion upper surface 23e has the connection electrodes 31 configured to be connected to the temperature sensor element 7. Hence, at least at the positions where the connection electrodes 31 are located, the sealing material 33 is away from the inner edge of the frame-portion upper surface 23e. In another viewpoint, for example, at least at the positions where the connection electrodes 31 are located, the width (the length from the inner edge to the outer edge) of the sealing material 33 is smaller than the width of the frame-portion upper surface 23e. At the positions other than where the connection electrodes 31 are located, the inner edges of the sealing material 33 may be away from the inner edges of the frame-portion upper surface 23e (the illustrated example) or may be aligned with the inner edges of the frame-portion upper surface 23e. In other words, at the positions other than where the connection electrodes 31 are located, the width of the sealing material 33 may be smaller than or equivalent to the width of the frame-portion upper surface 23e.

When the sealing material 33 is conductive, the sealing material 33 is, for example, away from the two connection electrodes 31 (the illustrated example). However, the sealing material 33 may be connected to one of the two connection electrodes 31 on the frame-portion upper surface 23e (see FIG. 9 described later). In this case, for example, the reference electric potential may be applied to one of the two connection electrodes 31 (in another viewpoint, one of two outer electrodes 7b of the temperature sensor element 7). When the sealing material 33 is insulating, the sealing material 33 may be in contact with one or both of the two connection electrodes 31.

In a configuration in which one connection electrode 31 is connected to a conductive sealing material 33 (for example, the first metal layer 35) (see FIG. 9 described later), the connection electrode 31 and the conductive sealing material 33 may be composed of materials different from each other or may be integrally formed by using the same material. In the latter configuration, it is not essential that the one connection electrode 31 and the first metal layer 35 can be distinguished from each other from their thicknesses and planar shapes. For example, the first metal layer 35 may overlap the total length and the total width of one side of the frame-portion upper surface 23e in transparent plan view, and part of the region of the first metal layer 35 may be used as one connection electrode 31.

As can be understood from the explanation above, the sealing material 33 may extend with a uniform width over the entire periphery (the illustrated example) or may extend with a varying width. Examples of the latter include a configuration in which the width of each side of the four sides of the frame-portion upper surface 23e is uniform, and the widths of the four sides differ from one another. In this case, for example, the width of the side of the sealing material 33 where the connection electrodes 31 are located may be smaller than the widths of the sealing material 33 on the sides where the connection electrodes 31 are not located. Example of another configuration in which the sealing material 33 extends with a varying width include one in which the width of each side varies. A more specific example is a configuration in which the width of the sealing material 33 is smaller only at and around the region where the connection electrodes 31 are located.

The specific size of the width of the sealing material 33 is not particularly limited. For example, the width of the sealing material 33 (for example, the minimum width) may be 1/10 or more, ⅕ or more, ⅓ or more, or ½ or more and ⅘ or less, ¾ or less, ⅔ or less, or ½ or less of the width of the frame-portion upper surface 23e (the width at the same position as that of the width of the sealing material 33 mentioned above in a peripheral direction). Any lower and upper limits mentioned above may be combined so as not to make a contradiction. Any lower limit and/or upper limit of the width of the frame-portion upper surface 23e explained earlier as examples and any lower limit and/or upper limit of the width of the sealing material 33 mentioned above may be combined.

The thickness of the sealing material 33 is, for example, uniform over the entire periphery. The specific value of the thickness of the sealing material 33 is not particularly limited. For example, the thickness of the sealing material 33 may be smaller than, equivalent to, or larger than the thickness (the minimum thickness or the maximum thickness) of the quartz crystal element 5 (or the quartz crystal blank 15). The thickness of the first metal layer 35 may be, for example, 10 μm or more and 30 μm or less or may be larger than this range. The thickness of the second metal layer 37 may be, for example, 10 μm or more and 40 μm or less or may be larger than this range.

### 1.3. Temperature Sensor Element (Including Portions of Package Related to Temperature Sensor Element)

### 1.3.1. Overview of Configuration of Temperature Sensor Element

As already mentioned, the temperature sensor element 7 is a film element in the present embodiment. The type of such a film temperature sensor element 7 (in another viewpoint, the temperature detection principle) is not particularly limited. For example, the temperature sensor element 7 may be a thermistor, a resistance temperature detector, a thermocouple, or a diode. The specific configuration of various types of temperature sensors is also not particularly limited. Note that the description of the embodiment may sometimes be expressed for convenience without a notation on the basis of an example of a configuration in which the temperature sensor element 7 is a thermistor.

Note that it may be judged rationally according to technical common senses that the temperature sensor element 7 is a film element and is not a chip temperature sensor element. For example, the temperature sensor element 7 includes one or more layers stacked on a film formation target (the lid 13), while a chip temperature sensor element is packaged, and the package is mounted with a joining material (for example, bumps). In another viewpoint, the absolute thickness of the temperature sensor element 7 and the relative thickness of the temperature sensor element 7 with respect to the thickness of the lid 13 and the like are not necessarily required to be extremely thin.

Although not illustrated, on the basis of an example in which the temperature sensor element 7 is a thermistor, an explanation will be given of the point that the specific configuration can be selected from various ones.

A thermistor includes, for example, as a basic constituent, a resistive film the resistance value of which varies according to temperature. The material of the resistive film may be, for example, an oxide (for example, a composite oxide) or a nitride (for example, a composite nitride). The oxide or the nitride may contain at least one selected from the group consisting of nickel (Ni), manganese (Mn), cobalt (Co), aluminum (Al), iron (Fe), and chromium (Cr). The resistive film may be, for example, only a film of one layer composed of a single material or a film of two or more layers composed of materials different from one another. The resistive film in plan view may be composed of the same material over the entire area or may be composed of different materials depending on the region.

The resistive film mentioned above may be stacked on a conductive or insulating lid lower surface 13b with an insulating film interposed therebetween or may be directly stacked on an insulating lid lower surface 13b. The insulating film has, for example, a resistivity higher than that of the resistive film. The material of the insulating film is not particularly limited. For example, it may be an inorganic material, an organic material, or a combination of both types of materials. Examples of inorganic materials include silicon dioxide (SiO₂) and silicon nitride (Si₃N₄). Examples of organic materials include various resins (for example, an epoxy-based resin and a silicone-based resin). The insulating film may be, for example, a film of only one layer composed of a single material or a film of two or more layers composed of materials different from one another. The insulating film in plan view may be composed of the same material over the entire area or may be composed of different materials depending on the region.

The resistive film may be exposed to the space (in another viewpoint, the inside of the recess R1) formed in the package 9 or may be covered with an insulating coating film. The coating film has, for example, a resistivity higher than that of the resistive film. The coating film, for example, may contribute to protecting the resistive film or electrodes described later. The material of the coating film is not particularly limited. For example, the explanation of the material of the insulating film in the previous paragraph may be applied to the coating film.

A voltage may be applied to the resistive film through a pair of application electrodes having appropriate locations and shapes. For example, the pair of application electrodes may be located at both ends of the resistive film in the longitudinal direction (or the lateral direction) in plan view and may apply a voltage to the resistive film in the longitudinal direction (or the lateral direction). In this configuration, at least the portions of the pair of application electrodes, connected to the resistive film may be stacked on a lower surface (on the lid 13 side) of the resistive film or may be stacked on an upper surface of the resistive film. The pair of application electrodes may face each other with the resistive film interposed therebetween in the thickness direction and may apply a voltage to the resistive film in the thickness direction. The pair of application electrodes may be a pair of comb electrodes stacked on the upper surface or the lower surface of the resistive film and engaged with each other.

When the application electrodes have portions not overlapping the upper surface (the surface opposite to the lid 13) of the resistive film, these portions, for example, may be stacked on a conductive or insulating lid lower surface 13b with the aforementioned insulating film (or another insulating film) interposed therebetween or may be directly stacked on an insulating lid lower surface 13b. The same or a similar explanation applies to the outer electrodes 7b and relay conductors described later. A conductive lid 13 may be used as an application electrode. A conductive lid 13 may be directly stacked on an application electrode or may be indirectly stacked on an application electrode with another conductor layer interposed therebetween, so that the lid 13 can be used as wiring for applying a voltage to the application electrode. However, the description of the embodiment may be sometimes expressed for convenience on the assumption of a configuration in which the lid 13 is not used as an application electrode or wiring.

The material of the application electrodes is not particularly limited. For example, at least part of the material of the application electrodes may be the same as at least one of the materials of the conductor patterns 17 and various conductors (3, 25, 27, 31, 35, and like) of the mount base 11 or may be different from those. In any way, the aforementioned explanation (specific examples of metals, whether a different material layer is present or not, whether a region composed of a different material is present or not, and the like) of the materials of various conductors used for the conductor patterns 17 and the mount base 11 may be applied to the explanation of the material of the application electrodes. The same or a similar explanation applies to the material of the outer electrodes 7b and relay conductors described later.

### 1.3.2. Correspondence Relationship Between Constituents of Temperature Sensor Film and Those in Drawings

As can be understood from the explanation above, the temperature sensor element 7 may have various constituents (for example, a resistive film, an insulating film, a coating film, and application electrodes). FIGS. 2 and 3 (and other drawings) illustrate the configuration of the temperature sensor element 7 as follows.

In FIGS. 2 and 3 (and other drawings), the temperature sensor element 7 includes a temperature sensor film 7a and the pair of outer electrodes 7b. A voltage is applied to the temperature sensor film 7a, for example, through the pair of outer electrodes 7b. In another viewpoint, the temperature sensor film 7a outputs a signal with a strength according to temperature from at least one of the pair of outer electrodes 7b.

As can be understood from the explanation above based on an example of the thermistor, the temperature sensor film 7a, for example, may include only a functional portion (for example, a resistive film in the case of a thermistor) directly contributing to temperature detection or may include an insulating film, a coating film, application electrodes, and/or relay conductors, described in the next paragraph, which overlap the functional portion.

In an example of a configuration in which the temperature sensor element 7 is a thermistor, the outer electrodes 7b may be part or all of application electrodes for directly applying a voltage to the resistive film (in direct contact with the resistive film) or may be electrodes electrically connected to the application electrodes. In the latter configuration, for example, the outer electrodes 7b may be directly connected to the application electrodes by partially overlapping the application electrodes or may be indirectly connected to the application electrodes with the relay conductors (for example, conductor layers different from both the application electrodes and the outer electrodes 7b) interposed therebetween.

In another viewpoint, the pair of outer electrodes 7b illustrated in in FIGS. 1 and 2 may be considered to be their entirety or may be considered to be parts of them. In the latter case, for example, a pair of outer electrodes 7b is covered with a coating film, and the parts mentioned above may be the parts of the pair of outer electrodes 7b, exposed from the coating film. The parts mentioned above may be considered to be the portions contributing to connection to the package 9 and selected for illustration out of the pair of outer electrodes 7b (the other portions of the pair of outer electrodes 7b are also exposed, but the illustration is omitted in the drawings).

As a specific example, for example, the temperature sensor element 7, as already mentioned, may include a pair of application electrodes located on both sides in a specified direction (for example, the direction in which the functional portion (the resistive film) extends) in plan view and overlapping the functional portion. In this case, the pair of outer electrodes 7b illustrated in FIG. 2 as an example may be, for example, parts of the pair of application electrodes (exposed portions or selected portions) or a pair of terminals directly or indirectly connected to the pair of application electrodes.

For example, as already mentioned, the temperature sensor element 7 may include a pair of application electrodes each on both sides of the resistive film in the thickness direction. In this case, the pair of outer electrodes 7b illustrated in FIG. 2 as an example may be portions (exposed portions or selected portions) of the pair of application electrodes or a pair of terminals directly or indirectly connected to a pair of application electrodes. In the former configuration, the pair of outer electrodes 7b may be an end portion of one application electrode in plan view and an end portion of the other application electrode in plan view.

Alternatively, for example, the temperature sensor element 7, as already mentioned, may include a pair of comb electrodes as a pair of application electrodes. The pair of outer electrodes 7b illustrated in FIG. 2 as an example may be portions (exposed portions or selected portions) of a pair of conductor patterns including a pair of comb electrodes or may be a pair of terminals directly or indirectly connected to a pair of comb electrodes. More specifically, the pair of comb electrodes may include, for example, a pair of busbars facing each other and a plurality of electrode fingers extending from each busbar to the other busbar. The parts of the pair of conductor patterns mentioned above may be, for example, portions extended from the pair of busbars. The pair of terminals mentioned above may be, for example, directly or indirectly connected to the pair of busbars.

Note that in plan view, the relationship between the shape of the temperature sensor element 7 and the arrangement of the one pair (or two or more pairs) of comb electrodes is not particularly limited. For example, as in the example in FIG. 2, when at least part (all in the example in FIG. 2) of the temperature sensor element 7 has a shape having the longitudinal direction and the lateral direction (which is referred to as a first shape in this paragraph), a pair of comb electrodes may be arranged such that a pair of busbars extends in the longitudinal direction and a plurality of electrode fingers extends in the lateral direction. In a configuration in which the temperature sensor element 7 has a plurality of first shapes, each first shape may have a pair of comb electrodes.

### 1.3.3. Position, Shape, and Dimensions of Temperature Sensor Element

The position (the position in the lid 13 (the same or a similar explanation applies in the following unless otherwise noted)), shape, and dimensions of the temperature sensor element 7 are not particularly limited. Note that the explanation of the position, shape, and dimensions of the temperature sensor element 7 may be applied to those of the temperature sensor film 7a unless a contradiction or the like occurs. As can be understood from the example of a thermistor mentioned above, in a configuration in which the temperature sensor film 7a includes only a functional portion (the resistive film in a thermistor), the position, shape, and dimensions of the temperature sensor film 7a refer to those of the functional portion and, in a configuration in which the temperature sensor film 7a includes other portions (an insulating film, a coating film, application electrodes, and/or relay conductors), the position, shape, and dimensions of the temperature sensor film 7a refer to those of the entire part including the functional portion and the other portions. However, in a configuration in which the temperature sensor film 7a includes other portions in addition to the functional portion, the explanation of the position, shape, and dimensions of the temperature sensor element 7 may be applied to those of the functional portion or the combination of the functional portion and other portions immediately above the functional portion, unless a contradiction or the like occurs.

As can be understood from other examples described later, the temperature sensor element 7 may be located in any region of the lid lower surface 13b. For example, in transparent plan view, the temperature sensor element 7 may be located within the recess R1 (in another viewpoint, inside the frame-portion upper surface 23e) (the examples in FIGS. 2 and 3), may be located outside the recess R1 (the example in FIG. 6 described later), or may be located so as to extend over the recess R1 and the outside of the recess R1. In other words, in transparent plan view, the temperature sensor element 7 may include, but is not limited to including, a portion overlapping the recess R1 and may include, but is not limited to including, a portion overlapping the outside of the recess R1. In another viewpoint, the temperature sensor element 7 may be in contact with the sealed space formed by the recess R1, but a configuration in which the temperature sensor element 7 is not in contact with the sealed space at all or substantially is possible.

In a configuration in which the temperature sensor element 7 overlaps the recess R1 in transparent plan view, the temperature sensor element 7 may overlap, but is not limited to overlapping, the geometric center of the recess R1. Whether the temperature sensor element 7 overlaps the recess R1 or the geometric center of the recess R1, the geometric center of the temperature sensor element 7 may approximately coincide, but is not limited to coinciding, with the geometric center of the recess R1. For example, when the distance between their geometric centers is ⅕ or less of the minimum length of the recess R1, their geometric centers may be considered to coincide with each other.

In a configuration in which the temperature sensor element 7 includes a portion overlapping the recess R1 in transparent plan view, the size of the overlapping portion is not particularly limited. For example, the area of the portion of the temperature sensor element 7 overlapping the recess R1 may be ⅕ or more, ⅓ or more, ½ or more, ⅔ or more, or ⅘ or more and 1 time or less, ⅘ or less, ⅔ or less, ½ or less, ⅓ or less, or ⅕ or less of the area of the recess R1. Any lower and upper limits mentioned above may be combined so as not to make a contradiction. In addition, the temperature sensor element 7 may overlap the entire recess R1. The lower limit and/or upper limit in this paragraph may be applied to the length (for example, the maximum length) of the portion of the temperature sensor element 7 overlapping the length (for example, the maximum length) of the recess R1 in any direction (for example, the longitudinal direction or the lateral direction) of the recess R1 in transparent plan view.

The above explanation of the position and size of the temperature sensor element 7 relative to the recess R1 (whether it overlaps the recess R1 or not, whether the geometric centers coincide with each other, the area of the portion overlapping the recess R1, and the like) may be applied to the explanation of the position and size of the temperature sensor element 7 relative to the quartz crystal element 5 or the excitation electrodes 19 with the words “recess R1” replaced with the words “quartz crystal element 5” or the words “excitation electrodes 19”.

In the illustrated example, the entire temperature sensor element 7 approximately overlaps the entire recess R1 in transparent plan view. In other words, in transparent plan view, the temperature sensor element 7 (more specifically, the temperature sensor film 7a) has the same shape and dimensions as those of the recess R1. Hence, the above explanation of the shape and dimensions of the recess R1 in plan view may be applied to the planar shape of the temperature sensor film 7a. Since the temperature sensor element 7 overlaps the entire recess R1 in transparent plan view, the temperature sensor element 7 overlaps also the entire quartz crystal element 5 and the entire excitation electrodes 19. In addition, in transparent plan view, the geometric center of the temperature sensor element 7 approximately coincides with or is relatively close to the geometric center of the recess R1, the geometric center of the quartz crystal element 5, and the geometric center of the excitation electrodes 19.

As a matter of course, unlike the illustrated example, the shape and dimensions of the temperature sensor element 7 may differ from those of the recess R1 in transparent plan view. For example, the temperature sensor element 7 may have a rectangular shape smaller than the recess R1 in transparent plan view. In this case, the longitudinal direction of the rectangle may be parallel to either the longitudinal direction or the lateral direction of the recess R1. The rectangle may be a square. In transparent plan view, the entire periphery of the temperature sensor film 7a may be away from the frame-portion upper surface 23e.

In transparent plan view, whether the shape of the temperature sensor element 7 is the same as that of the recess R1 or not, the temperature sensor element 7 may have a shape other than rectangular shapes. Examples of shapes other than rectangular shapes include circular shapes, elliptical shapes, and polygonal shapes other than rectangles. These shapes can be said to be ones similar to the boundaries of a convex set in mathematics. In addition, the temperature sensor element 7 may have a shape deviated from the boundaries of a convex set such as an L shape and a U shape.

The temperature sensor element 7 may have an approximately uniform thickness over the entire region or may have a plurality of regions having thicknesses different from one another. An upper surface of the temperature sensor element 7 may be, for example, a flat surface, a curved surface, or a shape having protrusions and recesses. Examples of the shape having protrusions and recesses include one having a plurality of planes having heights different from one another. Examples of such a shape include one that appears when the upper surface of the coating film covering a resistive film and/or relay conductors is affected by whether the resistive film and/or the relay conductors are present or not.

The specific thickness of the temperature sensor element 7 is not particularly limited. For example, the maximum thickness or the average thickness of the temperature sensor element 7 may be 1/300 or more, 1/200 or more, 1/100 or more, 1/50 or more, 1/30 or more, 1/10 or more, ⅕ or more, or ½ or more and 2 times or less, 1 time or less, ⅕ or less, 1/10 or less, or 1/100 or less of the minimum thickness, the average thickness, or the maximum thickness of the quartz crystal blank 15. Any lower and upper limits mentioned above may be combined so as not to make a contradiction. The thickness of the temperature sensor element 7 may be, for example, 0.05 μm or more, 0.1 μm or more, 1 μm or more, 5 μm or more, or 10 μm or more and 100 μm or less, 50 μm or less, or 10 μm or less. Any lower and upper limits mentioned above may be combined so as not to make a contradiction.

The value of a first distance (for example, the shortest distance or the average distance) between the temperature sensor element 7 and the quartz crystal element 5 is not particularly limited. For example, this first distance is smaller than, equivalent to, or larger than the thickness of the quartz crystal element 5 or the distance between the quartz crystal element 5 and the bottom surface of the recess R1 (for example, the shortest distance or the average distance).

As already mentioned, the quartz crystal element is not limited to ones in a plate shape and may have any shape such as a tuning-fork shape. In this case, the position, shape, and dimensions of the temperature sensor element may be determined so as to face a specific portion of the quartz crystal element. For example, in a configuration in which a quartz crystal element includes a base portion and an arm extending from the base portion and used for vibration, the temperature sensor element may have an elongated shape that faces the arm for vibration and does not face the base portion.

### 1.3.4. Positions, Shapes, and Dimensions of Outer Electrodes

The pair of outer electrodes 7b are located, for example, in a region of the lid 13 overlapping the frame-portion upper surface 23e in transparent plan view. This, when the lid 13 is placed to cover the recess R1, enables the pair of outer electrodes 7b to face the pair of the connection electrodes 31 located on the frame-portion upper surface 23e, so that these pairs of electrodes are connected to each other.

In transparent plan view, the pair of outer electrodes 7b may be located in any region on the frame-portion upper surface 23e. For example, each outer electrode 7b is located within one side (the illustrated example) out of the four sides of the frame-portion upper surface 23e, or each outer electrode 7b may extend over two or more sides. Note that in the following description, unless otherwise noted, and unless a contradiction or the like occurs, one outer electrode 7b may be considered to be located within one side.

In addition, for example, one outer electrode 7b may be located on any long side or short side of the four sides of the frame-portion upper surface 23e. The two outer electrodes 7b may be located on the same one side (the example in FIG. 2) or may be located on two sides different from each other (see FIGS. 4A and 4B described later). The two sides different from each other mentioned above may be two side facing each other or two side intersecting each other.

For example, one outer electrode 7b located within one side of the frame-portion upper surface 23e may be located in any region in the length direction of the one side. For example, one outer electrode 7b may extend over the length of one side (see FIG. 4B described later), may extend over part of one side (the examples in FIG. 2 and FIG. 4A described later). In the latter configuration, one outer electrode 7b may be located close to an end portion of one side (the illustrated example) or may be located close to the center of one side.

In transparent plan view, the pair of outer electrodes 7b are located, for example, inside the sealing material 33 (in another viewpoint, the second metal layer 37). More specifically, for example, the pair of outer electrodes 7b are located, for example, away from a conductive sealing material 33 (in another viewpoint, the first metal layer 35 and/or the second metal layer 37) (the illustrated example). However, one of the pair of outer electrodes 7b may be connected to the conductive sealing material 33 on the lid lower surface 13b (the frame-portion upper surface 23e). In this case, the one outer electrode 7b mentioned above, for example, may be one to which the reference electric potential is applied. One or both of the pair of outer electrodes 7b may be in contact or non-contact with an insulating sealing material 33.

In a configuration in which one outer electrode 7b is connected to a conductive sealing material 33 (for example, the second metal layer 37), these may be composed of materials different from each other or may be integrally formed by using the same material. In the latter configuration, it is not essential that the one outer electrode 7b and the second metal layer 37 can be distinguished from each other from their thicknesses and planar shapes. For example, the second metal layer 37 may have a size that covers the total length and the total width of one side of the frame-portion upper surface 23e in transparent plan view, and a region of the second metal layer 37 may be used as one outer electrode 7b.

In transparent plan view, as long as a pair of outer electrodes 7b are located inside the sealing material 33 as described above, the pair of outer electrodes 7b may be located in any region within the frame-portion upper surface 23e in the width direction (the direction from the inner edge to the outer edge). For example, the pair of outer electrodes 7b may be located inside the widthwise center of the frame-portion upper surface 23e or may overlap the widthwise center, or the pair of outer electrodes 7b may overlap the inner edge of the frame-portion upper surface 23e or may be away outward from the inner edge of the frame-portion upper surface 23e. The outer electrodes 7b may have a portion located inside the inner edges of the frame-portion upper surface 23e.

As can be understood from the above explanation of the positions, the shapes and dimensions of the outer electrodes 7b in plan view are not particularly limited. For example, the planar shape of each outer electrode 7b may be a rectangular shape located on one side of the frame-portion upper surface 23e (the illustrated example), may be approximately an L shape extending along two sides of the four sides of the frame-portion upper surface 23e, or may be approximately a U shape extending along three sides of the four sides of the frame-portion upper surface 23e. The shape of the outer electrode 7b located on one side is not limited to a rectangular shape and may be other shapes (for example, a circular shape, an elliptical shape, a polygonal shape other than rectangles, and the like).

For example, the length of one outer electrode 7b may be shorter than or longer than or equal to ½ of the length of one side of an inner edge of the frame-portion upper surface 23e. For example, the width of the outer electrode 7b may be smaller than or larger than or equal to ⅓ of the width of the frame-portion upper surface 23e.

As already mentioned, the temperature sensor film 7a may have any structure. For example, relay conductors may be interposed between the application electrodes that applies a voltage to the functional portion (the resistive film in a thermistor) and the outer electrodes 7b, and the relay conductors may electrically connect these two kinds of electrodes. In addition, at least two kinds of components selected from the group consisting of the application electrodes, the relay conductors, and the outer electrodes 7b may intersect one another in a manner of a multi-level crossing with an insulator interposed therebetween, and two or more (for example, two or more layers of) relay conductors may be interposed between the application electrodes and the outer electrodes 7b. As can be understood from this explanation, the outer electrodes 7b may have any positions, shapes, and dimensions regardless of those of the temperature sensor film 7a (functional portion).

For example, each outer electrode 7b may be located within the region where the temperature sensor film 7a (functional portion) is located or may have a different location. In the former configuration, the specific positions of the outer electrodes 7b relative to the temperature sensor film 7a are also not particularly limited. For example, the outer electrodes 7b may be located in a region adjacent to an edge portion of the temperature sensor film 7a or may be located in a region away from an edge portion of the temperature sensor film 7a (see FIG. 5A described later). In a configuration in which the outer electrodes 7b have a portion located outside the region where the temperature sensor film 7a is located, the outer electrodes 7b may extend from the positions overlapping the temperature sensor film 7a to any positions or may be located in any region and connected to the temperature sensor film 7a with relay conductors interposed therebetween. Note that in such a configuration, the temperature sensor film 7a may be located in a region away inward from the frame-portion upper surface 23e (for example, a region overlapping the quartz crystal element 5 or the excitation electrodes 19) in transparent plan view.

In the examples illustrated in FIGS. 1 to 3, in transparent plan view, the two outer electrodes 7b are located on the opposite side (the +D1 side) of the center of the package 9 to the side where the two pads 25 are located in the longitudinal direction of the package 9. More specifically, the two outer electrodes 7b are located on the +D1-side short side out of the four sides of the frame-portion upper surface 23e. The two outer electrodes 7b located on the +D1-side short side are located away from each other on both side in the extending direction of the short side. The two outer electrodes 7b overlap an inner edge portion of the frame-portion upper surface 23e.

The thickness of the outer electrodes 7b is not particularly limited. However, in the example in FIGS. 1 to 3, since the connection electrodes 31 and the outer electrodes 7b are joined so as to face each other between the planar lid lower surface 13b and the planar frame-portion upper surface 23e, the thickness of the outer electrodes 7b is smaller than that of the sealing material 33. Note that the thickness of the outer electrodes 7b can be set larger than or equal to that of the sealing material 33, for example, by setting the region where the connection electrodes 31 are located lower than the region where the first metal layer 35 is located on the frame-portion upper surface 23e. The thickness of the outer electrodes 7b may be smaller than, equivalent to, or larger than that of the second metal layer 37. Note that the explanation of the thickness of the outer electrodes 7b in this paragraph may be applied to the thickness of the connection electrodes 31. In this case, the words “second metal layer 37” may be replaced with the words “first metal layer 35”.

### 1.3.5. Portions of Package Related to Temperature Sensor Element

As already touched on, the package 9 (the mount base 11) includes the connection electrodes 31 configured to be connected to the two outer electrodes 7b. The connection electrodes 31 and the outer electrodes 7b are joined so as to face each other. In transparent plan view, the connection electrodes 31 and the outer electrodes 7b may nearly completely overlap each other, or may partially overlap each other. In any way, the above explanation of the positions, shapes, and dimensions of the outer electrodes 7b in transparent plan view may be applied to those of the connection electrodes 31 in transparent plan view unless a contradiction or the like occurs.

The two connection electrodes 31 are electrically connected to two terminals 3 with two pieces of wiring 27 interposed therebetween. It has already been mentioned that the wiring 27 may have various configurations. The piece of wiring 27 illustrated in FIG. 3 as an example, connecting a connection electrodes 31 to a terminal 3, includes only a via conductor extending through the frame portion 23b and the substrate portion 23a. In a configuration in which both of the two terminals 3 configured to be connected to the two connection electrodes 31 are located on one side in the longitudinal direction of the substrate portion 23a, a piece of wiring 27 connecting the pad 31 and the terminal 3 not illustrated in FIG. 3 may have the same or a similar structure. Whether the two terminals 3 connected to the two connection electrodes 31 are located at a pair of diagonal corners of the substrate portion 23a or not, the two pieces of wiring 27 connected to the two connection electrodes 31 may have a configuration other than the illustrated one.

The material of the connection electrodes 31 is also not particularly limited. For example, the material of the connection electrodes 31 may be the same as the material of various conductors used in the package 9 (3, 25, and/or 27) or may be the same as the material of the sealing material 33 (for example, the first metal layer 35). In any way, the explanation of the material of the various conductors used in the package 9 and/or the material of the sealing material 33 may be applied to the material of the connection electrodes 31.

The method of joining the outer electrodes 7b to the connection electrodes 31 is not particularly limited. For example, these two kinds of electrodes may be joined with a conductive joining material (not illustrated) interposed therebetween. The conductive joining material may be a conductive adhesive or a metal material. The metal material may be a solder (including lead-free solders (the same or a similar explanation applies in the following)) or a brazing material. The outer electrodes 7b and the connection electrodes 31 may be joined by direct metal-to-metal bonding. The method of joining the connection electrodes 31 and the outer electrodes 7b may be the same as or different from the method of joining the first metal layer 35 and the second metal layer 37.

The outer electrodes 7b and the connection electrodes 31 may be joined, for example, before the sealing process that joins the mount base 11 and the lid 13 with the sealing material 33. In the sealing process, the temperature of the outer electrodes 7b and the connection electrodes 31 (and a joining material when the joining material is interposed therebetween) may be, for example, lower than the heatproof temperature of the conductive adhesive that joins these electrodes or lower than the melting temperature of the metal material (which is a solder or a brazing material or may be the outer electrodes 7b themselves and/or the connection electrodes 31 themselves (the same or a similar explanation applies in the next paragraph)) that connects these electrodes. The metal material may be melted once and attached again.

Unlike the above explanation, the outer electrodes 7b and the connection electrodes 31 may be joined simultaneously with the sealing process that joins the mount base 11 and the lid 13 with the sealing material 33. For example, the heat in the sealing process may be used to solidify a conductive adhesive between the outer electrodes 7b and the connection electrodes 31 or may melt a metal material (in the state of being not joined to at least either the outer electrodes 7b or the connection electrodes 31) between the outer electrodes 7b and the connection electrodes 31. As a matter of course, an outer electrode 7b formed integrally with the second metal layer 37 with the same material as that of the second metal layer 37 may be joined to a connection electrode 31 in the sealing process.

Note that the outer electrodes 7b and the connection electrodes 31 may be joined after the sealing process. For example, in the sealing process, the temperatures of the outer electrodes 7b and the connection electrodes 31 are, for example, lower than the melting temperature of the metal material that connects these electrodes. After that, the outer electrodes 7b and the connection electrodes 31 may be heated by ultrasonic irradiation or the like, and the lid 13 may be locally pressed with an appropriate tool.

### 1.4. Other Examples According to First Embodiment

### 1.4.1. Other Examples of Outer Electrodes

FIGS. 4A and 4B are plan views of a lid lower surface 13b where a temperature sensor element 7A or 7B according to other examples is located.

As already mentioned, the positions, shapes, and dimensions of the outer electrodes 7b (in another viewpoint, the connection electrodes 31) may have various configurations. FIGS. 4A and 4B are diagrams of examples in which the positions, shapes, and dimensions of outer electrodes 7b differ from those illustrated in FIGS. 1 to 3 as an example. A specific description is as follows. Note that although not illustrated, the positions, shapes, and dimensions of the connection electrodes 31 configured to be connected to the outer electrodes 7b according to other examples are approximately the same as and/or similar to those of the outer electrodes 7b according to these other examples.

In the example illustrated in FIG. 4A, two outer electrodes 7b are adjacent to two edge portions (sides) different from each other of a temperature sensor film 7a having a rectangular shape (in other words, a shape in which four edge portions can be recognized). In another viewpoint, in transparent plan view, the two outer electrodes 7b overlap two sides different from each other on a frame-portion upper surface 23e having a rectangular shape (in other words, a shape in which four segments (sides) can be recognized). More specifically, the two outer electrodes 7b are located on the two short sides of the temperature sensor film 7a or the frame-portion upper surface 23e. The two outer electrodes 7b are located on the sides opposite to each other in the extending direction of the short sides (the D2 direction).

In the example illustrated in FIG. 4B, as in the example illustrated in FIG. 4A, two outer electrodes 7b are located on two sides different from each other (more specifically, the two short sides) of the temperature sensor film 7a (in another viewpoint, the frame-portion upper surface 23e). Each outer electrode 7b extends along most (for example, 80% or more (all in the illustrated example)) of the length (the length on the inner peripheral side on the frame-portion upper surface 23e) of each side.

### 1.4.2. Other Examples of Temperature Sensor Film

FIGS. 5A, 5B, and 5C are cross-sectional partial views of quartz crystal resonators 1C, 1D, and 1E according to other examples. These views correspond to an upper portion of FIG. 3.

As already mentioned, the position, shape, and dimensions of the temperature sensor film 7a may have various configurations. FIGS. 5A to 5C illustrate examples in which the position, shape, and dimensions differ from those illustrated in FIGS. 1 to 3 as an example. A specific description is as follows.

Note that in terms of the positions of two outer electrodes 7b, FIGS. 5A to 5C are based on an example of a configuration in which the two outer electrodes 7b are located on the +D1-side of the frame-portion upper surface 23e as in the embodiment. However, as can be understood from the explanation above, the two outer electrodes 7b may be located at any positions and may be, for example, at the positions shown in FIGS. 4A and 4B as examples or positions similar to these.

In the example illustrated in FIG. 5A, a temperature sensor film 7a of a temperature sensor element 7C includes a portion located outside the recess R1 in transparent plan view. More specifically, the temperature sensor film 7a overlaps the entire surface of the lid lower surface 13b. Along with this, a sealing material 33C of a package 9C is joined to the lid lower surface 13b with the temperature sensor film 7a interposed therebetween.

In configurations in which the temperature sensor film 7a includes a portion located outside the recess R1 (including examples in FIGS. 5B and 6 described later), the size of the portion is not particularly limited. For example, in transparent plan view, the area of the portion located outside the recess R1 (and/or a portion overlapping the frame-portion upper surface 23e) may be ⅕ or more, ⅓ or more, ½ or more, ⅔ or more, ⅘ or more, or 1 time or more of the area of the frame-portion upper surface 23e. In the explanation above, the words “area” may be replaced with the words “length of the frame-portion upper surface 23e in the width direction”.

In the explanation in the previous paragraph, the words “recess R1” may be replaced with the words “quartz crystal element 5”. In this case, the words “frame-portion upper surface 23e” may be replaced with the words “region from the outer edges of the quartz crystal element 5 to the inner edges or the outer edges of the frame-portion upper surface 23e”. In the explanation in the previous paragraph, the words “recess R1” may be replaced with the words “excitation electrodes 19”. In this case, the words “frame-portion upper surface 23e” may be replaced with the words “region from the outer edges of the excitation electrodes 19 to the outer edges of the quartz crystal element 5” or the words “region from the outer edges of the excitation electrodes 19 to the inner edges or the outer edges of the frame-portion upper surface 23e”.

Note that the sealing material 33C may be a conductive material (for example, a metal) or an insulating material (for example, glass). In the former configuration, the temperature sensor film 7a may have an insulating coating film between the functional portion (the resistive film in a thermistor) and the sealing material 33C. In the latter configuration, the temperature sensor film 7a may have, but is not limited to having, a coating film. In FIG. 5A, the sealing material 33C is depicted as a material of one layer. However, as in the embodiment, the sealing material 33C may include the first metal layer 35 and the second metal layer 37.

In the example illustrated in FIG. 5B, a temperature sensor film 7a of a temperature sensor element 7D includes a portion located outside the recess R1 in transparent plan view, as in the example illustrated in FIG. 5A. However, in the temperature sensor element 7D, the temperature sensor film 7a does not overlap the entire surface of a lid lower surface 13b and overlaps part of the lid lower surface 13b. More specifically, the outer edges (for example, all of the outer edges) of the temperature sensor film 7a are located inside the outer edges of the lid lower surface 13b (in another viewpoint, the frame-portion upper surface 23e). Note that in a package 9D illustrated in FIG. 5B, a mount base 11D and a lid 13 may be joined in the regions surrounding the temperature sensor film 7a (the temperature sensor element 7D) (the illustrated example) as in the embodiment, or they may be joined with the temperature sensor film 7a interposed therebetween as in the example in FIG. 5A.

The temperature sensor element 7D illustrated in FIG. 5B is also an example of a configuration in which the temperature sensor film 7a is thicker than the sealing material 33. In such a configuration, on the frame-portion upper surface 23e, the region where the connection electrodes 31 are located may be lower (may be located closer to the bottom surface of the recess R1) than the region where the sealing material 33 is located. This reduces the probability that the airtightness of the recess R1 can decrease depending on the thickness of the temperature sensor film 7a.

Note that the method of making the region where the connection electrodes 31 are located lower than the region where the sealing material 33 is located on the frame-portion upper surface 23e is not particularly limited. For example, as in the formation of the recess R1, a ceramic green sheet may be stacked on the region where the sealing material 33 is to be located to make the region relatively high, or the region where the connection electrodes 31 are to be located may be made relatively low by press working. The region where the connection electrodes 31 are to be located may be made relatively low by performing polishing, grinding, cutting, or laser processing on the region.

In the example illustrated in FIG. 5C, a temperature sensor film 7a of a temperature sensor element 7E nearly completely overlap the entire recess R1 in transparent plan view, as in the embodiment. In this case, the temperature sensor film 7a is located in a recess (the symbol of which is omitted) in a lid lower surface 13b. The thickness of the temperature sensor film 7a is smaller than, equivalent (the illustrated example) to, or larger than the depth of the recess in the lid lower surface 13b. Note that this example is applicable not only to the temperature sensor film 7a having a size extending over the entire recess R1 but also to temperature sensor films 7a having various sizes the entirety of which is located inside the outer edges of the lid 13.

Note that in a package 9E, a lid 13E and a mount base 11 may be joined, for example, as in the embodiment or other examples. For example, since the temperature sensor film 7a is located in the recess of the lid 13E, the −D3-side surface of the temperature sensor film 7a is located further on the +D3 side than in the embodiment. Accordingly, for example, this reduces the probability that the region where the connection electrodes 31 are located on the frame-portion upper surface 23e needs to be lower than the region where the sealing material 33 is located as in the example in FIG. 5B.

FIG. 6 is a perspective view of a temperature sensor element 7F according to another example.

As already mentioned, the planar shape of the temperature sensor film 7a may be selected from various shapes and is not limited to a rectangular shape or the like. As for the temperature sensor element 7F, the planar shape of the temperature sensor film 7a is frame-shaped (annular). In other words, the temperature sensor film 7a has a shape extending along (for example, parallel to) one or more edge portions of a lid 13 (in another viewpoint, one or more sides of a frame-portion upper surface 23e). The shape extending along edge portions is not limited to an annular shape. For example, the temperature sensor film 7a may extend along only one side of the rectangular lid 13, may extend along only two sides (may be L-shaped), may extend along only three sides (may be U-shaped), or may have a shape extending along the four sides but having a gap at a certain position (may be C-shaped).

The temperature sensor film 7a of the temperature sensor element 7F may be considered to include one or more segments (the symbols of which are omitted) extending along one or more edge portions of the lid 13. Each segment is approximately rectangular. In another viewpoint, each segment extends with a uniform width. Each segment extends along approximately the entire length of one edge portion (for example, 80% or more of the length). As a matter of course, as can be understood from the explanation above, in each segment, the planar shape is not limited to a rectangular shape, the width may vary, and the length is shorter than that of one edge portion. The shapes and dimensions of the segments may be the same as or different from one another.

The temperature sensor film 7a extending along one or more edge portions of the lid 13 in transparent plan view may overlap, but is not limited to overlapping, the recess R1. The example in FIG. 6 is on the assumption of a configuration in which the temperature sensor film 7a does not overlap the recess R1 (or the overlapping area is relatively small). For example, the inner edges of the temperature sensor film 7a are approximately aligned with the edge portions of the recess R1 in transparent plan view. Note that the temperature sensor film 7a in FIG. 6 is an example of a configuration in which the temperature sensor film 7a includes a portion located outside the recess R1 in transparent plan view as in the examples in FIGS. 5A and 5B.

In transparent plan view of the temperature sensor film 7a having a shape extending along the edge portions of the lid 13, the size of the region of the recess R1 not overlapping the temperature sensor film 7a (the region surrounded by the temperature sensor film 7a), the size of the region where the temperature sensor film 7a and the recess R1 overlap each other, and the size of the region of the temperature sensor film 7a not overlapping the recess R1 (the region outside the recess R1) are not particularly limited. For example, in transparent plan view, the area of the region of the temperature sensor film 7a outside the recess R1 may be ½ or more, ⅔ or more, ⅘ or more, or 1 time of the area of the entire temperature sensor film 7a. In this explanation, the word “area” may be replaced with the words “width of the temperature sensor film 7a (segment)”. In transparent plan view, for example, the area of the region of the recess R1 surrounded by the temperature sensor film 7a may be ½ or more, ⅔ or more, ⅘ or more, or 1 time of the area of the entire recess R1. In this explanation, the word “area” may be replaced with the words “length (for example, the maximum length) of the recess R1 in any direction (for example, the longitudinal direction or the lateral direction) in transparent plan view”. Also in the explanation in this paragraph, the words “recess R1” may be replaced with the words “quartz crystal element 5” or the words “excitation electrodes 19”.

As already mentioned, the temperature sensor film 7a may have various configurations (for example, the shape of the application electrodes). The same or a similar explanation also applies to the temperature sensor element 7F. For example, as for the temperature sensor element 7, a voltage may be applied to both ends of the temperature sensor film 7a in the extending direction of one or more segments (sides) included in the temperature sensor film 7a, a voltage may be applied to the temperature sensor film 7a in the thickness direction, or a voltage may be applied through one or more pairs of comb electrodes. In a configuration including comb electrodes, for example, each segment may have a pair of comb electrodes. In this case, for example, a pair of comb electrodes may be located in such an orientation that a pair of busbars extends in the longitudinal direction of each segment.

As already mentioned, the positions, shapes, and dimensions of the two outer electrodes 7b are not particularly limited as long as the two outer electrodes 7b have portions overlapping the frame-portion upper surface 23e in transparent plan view. In the example in FIG. 6, two outer electrodes 7b are located at a pair of diagonal corners of the temperature sensor film 7a in the form of a rectangular frame. Their shapes are squares having a length the same as or similar to the width of the segment (side) of the temperature sensor film 7a. As a matter of course, the two outer electrodes 7b may be located in a region other than the pairs of diagonal corners (for example, see FIG. 2 or 4B) and may have shapes other than squares (for example, rectangular shapes other than squares or circular shapes).

The temperature sensor film 7a extending along one or more edge portions of the lid 13 in transparent plan view may overlap the sealing material 33 as in the example in FIG. 5A or may have a configuration in which the temperature sensor film 7a does not overlap the sealing material 33 as in the example in FIG. 5B. FIG. 6 illustrates an example of the former configuration. Note that this figure illustrates a configuration in which a second metal layer 37 is located on the lid 13 for convenience. As can be understood from the explanation above, the sealing material 33 may be insulating (for example, glass), and the sealing material 33 may be located only on the mount base 11 before the lid 13 and the mount base 11 are joined.

### 1.5. Summary of First Embodiment

As described above, the piezoelectric device (the quartz crystal resonator 1) includes the piezoelectric element (the quartz crystal element 5), the mount base 11, and the temperature sensor element 7. The mount base 11 includes the recess R1 configured to be hermetically sealed. The quartz crystal element 5 is mounted on the bottom surface of the recess R1. The temperature sensor element 7 includes a portion located closer to the upper end of the recess R1 (the lid 13 side) than the quartz crystal element 5.

Hence, for example, as already mentioned, this configuration reduces the probability that the temperature sensor element 7 can be excessively affected by the heat from the bottom surface of the recess R1. Hence, the measured temperature is likely to follow the temperature of the quartz crystal element 5.

The piezoelectric device (the quartz crystal resonator 1) may include the lid 13 closing the recess R1.

In this case, for example, the configuration of the lid 13 can be the same as or similar to that of a conventional lid, compared with the configuration in which the temperature sensor element 407 also serves as a lid as in a fourth embodiment described later. This, for example, makes it easy to ensure the package 9 a sufficient strength. In addition, conventional knowledge can be used for the temperature difference between the outside and the inside of the package 9.

The temperature sensor element 7 may include the temperature sensor film 7a stacked on the first surface (the lid lower surface 13b) of the lid 13 on the mount base 11 side.

In this case, for example, since the temperature sensor element 7 is fixed to the lid 13, the quartz crystal element 5 can be inspected through the mount base 11, and the excitation electrodes 19 can be trimmed with laser light to adjust the frequency characteristics after the quartz crystal element 5 is mounted on the mount base 11 and before the temperature sensor element 7 is fixed to the mount base 11 (with the lid 13 interposed therebetween). Hence, for example, when a quartz crystal element 5 and the mount base 11 are determined to be defective in the inspection mentioned above, the temperature sensor element 7 will not be wasted. In addition, for example, the temperature sensor element 7 will not be trimmed with laser light. When the temperature sensor element 7 and the lid 13 are separate components, after the frequency is adjusted with laser light or the like, the frequency characteristics can change both when the temperature sensor element 7 is fixed to the mount base 11 and when the lid 13 is fixed to the mount base 11. This can, in turn, increase change in the frequency characteristics. However, since both parts are fixed at a time, the change in the frequency characteristics is likely to reduce. As described above, since frequency adjustment is easier, for example, the productivity will increase. In addition, since the temperature sensor element 7 includes the temperature sensor film 7a in this configuration, the vibrator 1 can be made thinner more easily than the configuration in which the temperature sensor element 7 is of a chip type (such a configuration is also included in the technology according to the present disclosure). In addition, this configuration also reduces the probability of the mount base 11 or the like inadvertently coming into contact with a side surface of the temperature sensor element 7 in the course of joining the lid 13 to the mount base 11. In a configuration in which a reference electric potential is applied to the lid 13 and the temperature sensor element 7, communization of the terminals 3 and the wiring 27 for applying the reference electric potential to both components is easy because the temperature sensor element 7 is provided on the lid 13.

The temperature sensor film 7a may include a portion overlapping the recess R1 (or the quartz crystal element 5 or the excitation electrodes 19) in transparent plan view. For example, the temperature sensor film 7a may overlap ⅓ or more, ½ or more, or all of the area of the recess R1 (or the quartz crystal element 5 or the excitation electrodes 19) in transparent plan view (see FIGS. 1 to 5C).

In this case, for example, in a configuration in which the temperature sensor film 7a can detect the temperature of the quartz crystal element 5 through gas in the recess R1, the measured temperature is more likely to follow the temperature of the quartz crystal element 5. For example, since the necessity of allocating an area to the temperature sensor film 7a on the frame-portion upper surface 23e reduces, structural interference between a component for sealing the recess R1 (for example, the sealing material 33) and the temperature sensor film 7a can be avoided easily. This, for example, simplifies the configuration of the temperature sensor film 7a.

The temperature sensor film 7a may include a portion located outside the recess R1 (or the quartz crystal element 5 or the excitation electrodes 19) in transparent plan view. For example, the temperature sensor film 7a may overlap ⅕ or more, ⅓ or more, ½ or more, or all of the area of the frame-portion upper surface 23e in transparent plan view (see FIGS. 5A, 5B, and 6).

In this case, for example, in a configuration in which the temperature sensor film 7a extends outward from the region overlapping the recess R1 as in FIGS. 5A and 5B, a sufficient area can be easily ensured for the temperature sensor film 7a. Hence, for example, this is advantageous to downsizing the vibrator 1 in plan view. For example, in a configuration in which the temperature sensor film 7a does not overlap the recess R1 (or the quartz crystal element 5 or the excitation electrodes 19) as in FIG. 6, for example, contact between the temperature sensor film 7a and the quartz crystal element 5 can be avoided. In another viewpoint, this is advantageous to making the vibrator 1 thinner. In addition, in a configuration in which the space between the quartz crystal element 5 and the temperature sensor film 7a has high heat insulation, for example, when the recess R1 is under vacuum, the temperature of the temperature sensor film 7a is likely to be equivalent to the temperature of the quartz crystal element 5 by the interposition of the frame portion 23b. This in turn makes it likely for the measured temperature to follow the temperature of the quartz crystal element 5.

### 2. Second Embodiment

FIG. 7 is a cross-sectional view of a quartz crystal resonator 201 according to the second embodiment. This figure corresponds to FIG. 3 in the first embodiment.

In the first embodiment, the temperature sensor element 7 is a film element, while in the second embodiment, a temperature sensor element 207 is a chip element. The temperature sensor element 207 is mounted on a lid 13 with a conductive joining material 41. Also in this configuration, the temperature sensor element 207 is located closer to the lid 13 than a quartz crystal element 5 as in the first embodiment. Hence, this configuration provides effects the same as or similar to those of the first embodiment. For example, this configuration reduces the effects that the heat from the circuit substrate 53 on which a vibrator 1 is mounted exerts on the temperature sensor element 207. A specific description is, for example, as follows.

The specific configuration of the temperature sensor element 207 is not particularly limited. For example, the temperature sensor element 207 may have various principles such as a thermistor, a resistance temperature detector, a thermocouple, or a diode, as with the temperature sensor element 7. For example, the functional portion of the temperature sensor element 207 (for example, a resistor in a thermistor) may be exposed to the outside (the space in a recess R1) or may be covered with a sealing portion. The material of the sealing portion is not particularly limited and may be, for example, an insulating material such as glass, a ceramic, or a resin.

In the illustrated example, the temperature sensor element 207 includes an element body 207a and two element terminals 207b (only one of which is illustrated). As can be understood from the previous paragraph, the element body 207a includes, for example, at least a functional portion and may include a sealing portion that covers the functional portion. The shape of the element body 207a may be, for example, approximately a thin rectangular parallelepiped (more specifically, a plate shape in the illustrated example). The two element terminals 207b are located, for example, on the surface of the element body 207a on the lid 13 side (on the +D3 side). In the above explanation, the element terminals 207b may be, for example, layer-shaped conductors stacked on the +D3-side surface of the element body 207a or may be conductors (which are not necessarily layer-shaped conductors) including at least portions exposed on the +D3-side surface of the element body 207a.

To the position, shape, and dimensions of the element body 207a (the temperature sensor element 207) in transparent plan view, the explanation of the position, shape, and dimensions of the temperature sensor film 7a located within the recess R1 in transparent plan view may be applied unless a contradiction or the like occurs. For example, the element body 207a may overlap the whole or part of the recess R1 (or the quartz crystal element 5 or excitation electrodes 19). A geometric center of the element body 207a may coincide, but is not limited to coinciding, with the geometric center of the recess R1 (or the quartz crystal element 5 or the excitation electrodes 19).

The thickness and the position in the thickness direction (the D3 direction) of the element body 207a are not particularly limited. For example, the thickness of the element body 207a may be smaller than, equivalent to, or larger than the thickness of the quartz crystal element 5 (or a quartz crystal blank 15). Each of the distance between the element body 207a and the quartz crystal element 5 and the distance between the element body 207a and the lid 13 may be shorter than, equivalent to, or longer than the distance between the quartz crystal element 5 and the bottom surface (a first substrate surface 23c) of the recess R1.

The positions, shapes, and dimensions of the element terminals 207b are not particularly limited as long as the element terminals 207b and a lid lower surface 13b (more specifically, the region of the lid lower surface 13b facing the recess R1) can be joined with a joining material 41. For example, a typical chip temperature sensor element includes two element terminals on both ends in the longitudinal direction. The element terminal at each end portion is stacked only on the lower surface (in this case, the +D3-side surface) or on the whole of each end portion (the five surfaces excluding the other end side). The element terminals 207b may have such a configuration.

In the illustrated example, the two element terminals 207b are located adjacent to an edge portion (an edge portion extending in the D2 direction or a short side) of the element body 207a on one side (on the +D1 side) in the longitudinal direction (which can be the lateral direction) and side by side along (for example, parallel to) the edge portion. The element body 207a is supported in a manner of a cantilever by the two element terminals 207b being joined to the lid lower surface 13b with two pieces of joining material 41 (only one of which is illustrated). In the illustrated example, the element terminals 207b include only first portions stacked on the surface of the element body 207a on the lid 13 side (the +D3 side). The element terminals 207b may include, in addition to the first portions mentioned above, portions stacked on other surfaces (on the +D1 side, a +D2 side, a −D2 side, and/or the −D3 side).

The positions of the two element terminals 207b relative to a mount base 11 are not particularly limited. For example, the two element terminals 207b may be located at an end portion of the recess R1 in a specified direction (for example, the longitudinal direction or the lateral direction) in transparent plan view or may be located relatively far away from the end portion mentioned above (for example, at the center in the specified direction mentioned above). In the former case, the two element terminals 207b may be located at any two corners of the four corners or may be located away from the four corners.

In the illustrated example, the two element terminals 207b are located on the side (the +D1 side) of the geometric center of the recess R1 opposite to the side where extension electrodes 21 (pads 25) are located in transparent plan view, more specifically, at the two corners on the +D1 side of the recess R1. As a matter of course, unlike the illustrated example, the two element terminals 207b may be located on the side (the −D1 side) of the geometric center of the recess R1 where the extension electrodes 21 (pads 25) are located in transparent plan view, and they may be located at the two corners of the recess R1 on the −D1 side.

A package 209 is configured such that the temperature sensor element 207 can be mounted on the lid lower surface 13b. The specific configuration is not particularly limited. In the illustrated example, as for the lid 13, at least the lid lower surface 13b (for example, the entire lid 13) is composed of an insulating material. A conductor pattern 39 is stacked on the lid lower surface 13b. The conductor pattern 39 may include, although symbols are not attached, for example, a first portion to which the joining material 41 is joined, a second portion that is joined to connection electrodes 31, and a wiring portion connecting these portions. The specific shape, dimensions, and material of the conductor pattern 39 are not particularly limited.

The material of the joining material 41 is not particularly limited. For example, the material of the joining material 41 may be the same as or different from that of a joining material 29. The joining material 41 may be a conductive adhesive or a solder. To the joining between the conductor pattern 39 and the connection electrodes 31, the explanation of the joining between the outer electrodes 7b and the connection electrodes 31 may be applied.

In FIG. 7, the symbol 33C of the sealing material shown in FIG. 5A is indicated as a sealing material with which the lid 13 and the mount base 11 are joined. However, the sealing material may be conductive or insulating and may be the one the same as the material on the mount base 11 side or the material on the lid 13 side (for example, a first metal layer 35 and a second metal layer 37).

As described above, the piezoelectric device (the quartz crystal resonator 201) includes the piezoelectric element (the quartz crystal element 5), the mount base 11, and the temperature sensor element 207. The temperature sensor element 207 includes a portion (in the illustrated example, the entire temperature sensor element 207) located closer to the upper end of the recess R1 (the lid 13 side) than the quartz crystal element 5. As already mentioned, this configuration, for example, reduces the probability that the temperature sensor element 207 can be excessively affected by the heat from the bottom surface of the recess R1. Hence, the measured temperature is likely to follow the temperature of the quartz crystal element 5.

The temperature sensor element 207 may be a chip element mounted on the surface (the lid lower surface 13b) of the lid 13 on the mount base 11 side.

In this case, for example, a temperature sensor element 207 commercially available can be used for the vibrator 201. For example, as in the configuration in which the film temperature sensor element 7 is held by the lid 13, when the quartz crystal element 5 and the mount base 11 are determined to be defective in an inspection after the quartz crystal element 5 is mounted on the mount base 11 and before the lid 13 is joined to the mount base 11, the lid 13 and the temperature sensor element 207 will not be wasted.

### 3. Third Embodiment

FIG. 8 is a cross-sectional view of a quartz crystal resonator 301 according to the third embodiment. This figure corresponds to FIG. 7 in the second embodiment.

In the third embodiment, as in the second embodiment, a chip temperature sensor element 207 is located closer to a lid 13 than a quartz crystal element 5. However, although the temperature sensor element 207 is mounted on the lid 13 in the second embodiment, the temperature sensor element 207 in the third embodiment is mounted at a wall portion of a recess R1 (a frame portion 23b). A specific description is, for example, as follows.

In a package 309 of the third embodiment, a mount base 311 includes a step portion in a wall portion of the recess R1. In other words, the frame portion 23b includes a surface (the symbol of which is omitted) facing the lid 13 at a position lower than an upper surface to which the lid 13 is joined. Connection electrodes 31 are located on this surface. The temperature sensor element 207 is mounted on the wall portion of the recess R1 by element terminals 207b being joined to the connection electrode 31 with a joining material 41.

Note that the frame portion 23b may be considered to include a first frame portion 23ba stacked on a substrate portion 23a and a second frame portion 23bb stacked on the first frame portion 23ba. The width of the second frame portion 23bb is reduced relative to the first frame portion 23ba on the inner edge side at least in a portion in the peripheral direction. As can be understood from the explanation of the substrate portion 23a and the frame portion 23b in the first embodiment, the first frame portion 23ba and the second frame portion 23bb may be fabricated by being stacked to each other or may be fabricated by a manufacturing method different from such a manufacturing method (for example, press working).

To the position, shape, and dimensions of an element body 207a (the temperature sensor element 207) in transparent plan view, the explanation of the position, shape, and dimensions of the temperature sensor film 7a located within the recess R1 in transparent plan view may be applied as in the second embodiment unless a contradiction or the like occurs. To the thickness and the position in the thickness direction (the D3 direction) of the element body 207a, the explanation in the second embodiment may be applied.

To the position, shape, and dimensions of the element terminals 207b in plan view, for example, the explanation of the positions, shapes, and dimensions of the outer electrodes 7b in plan view in the first embodiment may be applied. When this explanation is applied, for example, the position of the inner edge of the upper surface of the first frame portion 23ba in transparent plan view may be considered to correspond to the position of the inner edge of the frame-portion upper surface 23e in the explanation in the first embodiment.

As described above, the piezoelectric device (the quartz crystal resonator 301) includes the piezoelectric element (the quartz crystal element 5), the mount base 311, and the temperature sensor element 207. The temperature sensor element 207 includes a portion (in the illustrated example, the entire temperature sensor element 207) located closer to the upper end of the recess R1 (the lid 13 side) than the quartz crystal element 5. For example, as already mentioned, this configuration reduces the probability that the temperature sensor element 207 can be excessively affected by the heat from the bottom surface of the recess R1. Hence, the measured temperature is likely to follow the temperature of the quartz crystal element 5.

The temperature sensor element 207 may be a chip element mounted at a wall portion of the recess R1 (the frame portion 23b).

In this case, for example, a commercially available temperature sensor element 207 can be used for the vibrator 301 as in the second embodiment. In addition, the configuration of the lid 13 can be the same as or similar to a conventional one.

### 4. Fourth Embodiment

### 4.1. Quartz Crystal Resonator

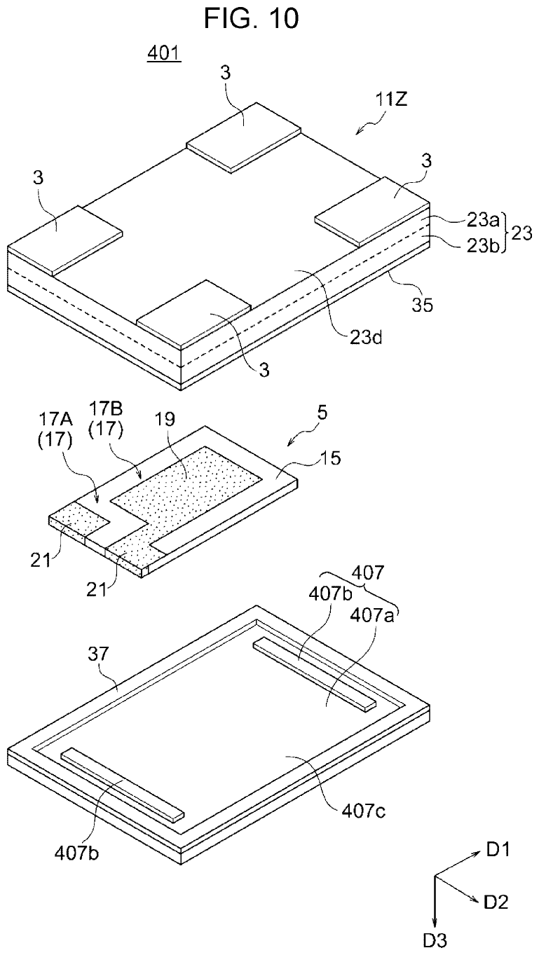

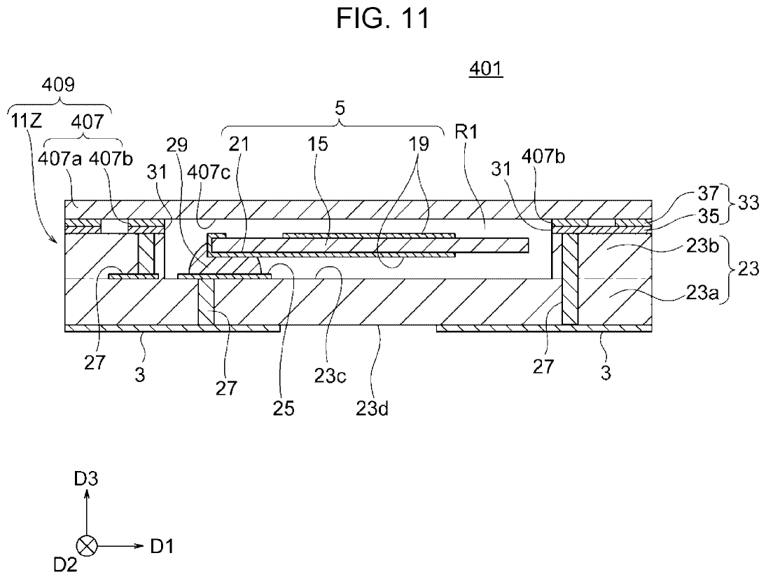

FIG. 9 is an exploded perspective view of a quartz crystal resonator 401 according to the fourth embodiment illustrating its configuration. FIG. 10 is an exploded perspective view of the quartz crystal resonator 401 from the side opposite to the view in FIG. 9. FIG. 11 is a cross-sectional view taken along line XI-XI in FIG. 9.

In the fourth embodiment, the lid is composed of a chip temperature sensor element 407. In other words, the temperature sensor element 407 is not held by a package 409 (the symbol of which is in FIG. 11) but serves as part of the package 409. In other words, the package 409 includes a mount base 11Z and the temperature sensor element 407 (the lid).

The mount base 11Z may be basically the same as or similar to the mount base 11 in the first embodiment (and other examples according to the first embodiment (the same or a similar explanation applies in the following)). In other words, various mount bases according to the fourth embodiment and other examples, which will be described below, may be applied to the first embodiment (the configurations in which the lid 13 and the temperature sensor element 7 are separate components). In this case, small differences in specific dimensions and the like are allowed between the mount base in the first embodiment and the mount base in the fourth embodiment.

The thickness of a frame portion 23b (the depth of a recess R1) or the height from a first substrate surface 23c to a body lower surface 407c described later of the temperature sensor element 407 may be determined as appropriate, for example, depending on the thickness of a quartz crystal element 5 and the like. In the present embodiment, unlike the first to third embodiments, the temperature sensor element 407 need not be located within the sealed space formed by the recess R1. Hence, in the setting of dimensions mentioned above such as the depth of the recess R1, the thickness of the temperature sensor element 407 need not be taken into account. Hence, the dimensions mentioned above may be, for example, the same as or similar to those of a conventional vibrator. As a matter of course, the explanation of dimensions such as the depth of the recess R1 mentioned in the description of the first embodiments may be applied to the present embodiment.

The size of the recess R1 in plan view may be determined as appropriate, for example, in consideration of the size of the quartz crystal element 5 in plan view, as in the first embodiment. In the present embodiment, unlike the first to third embodiments, the temperature sensor element 407 need not be located within the sealed space formed by the recess R1. Hence, when the size of the recess R1 in plan view is determined, the thickness of the temperature sensor element 407 need not be taken into account. As a matter of course, the size of the temperature sensor element 407 in plan view may be taken into account as necessary. The above situation does not preclude the explanation of the size of the recess R1 in plan view in the first embodiment from being applied to the present embodiment.

To the chip temperature sensor element 407, the explanation or the like of the chip temperature sensor element 207 in the second embodiment may be applied as appropriate unless a contradiction or the like occurs. For example, the temperature sensor element 407, as with the temperature sensor element 207, includes an element body 407a and a pair of element terminals 407b. A voltage is applied to the element body 407a, for example, through the two element terminals 407b. In another viewpoint, the element body 407a outputs a signal with a strength according to temperature from at least one of the two element terminals 407b.

The two element terminals 407b are, for example, exposed to the outside of the element body 407a (more specifically, on the mount base 11Z side (the −D3 side)). In this explanation, the element terminals 407b may be, for example, layer-shaped conductors stacked on the −D3-side surface of the element body 407a (which is sometimes referred to as “body lower surface 407c”) or may be conductors including at least portions exposed on the body lower surface 407c (which are not necessarily layer-shaped conductors). The material of the element terminals 407b is not particularly limited. For example, the explanation of the material of various conductors in the mount base 11 (11Z) may be applied to the material of the element terminals 407b.

Note that the explanation of the position, shape, and dimensions of the temperature sensor element 407 according to the embodiment may be applied to those of the element body 407a, unless otherwise noted, and unless a contradiction or the like occurs. Whether the element body 407a includes only the functional portion or includes portions (for example, the sealing portion) other than the functional portion, the explanation of the position, shape, and dimensions of the temperature sensor element 407 may be applied to those of the functional portion, unless otherwise noted, and unless a contradiction or the like occurs.

The shape and dimensions of the temperature sensor element 407, as with those of the lid 13 in the first to third embodiments, are not particularly limited as long as the temperature sensor element 407 is configured to close the recess R1. The explanation of the shape and dimensions of the lid 13 may be applied to the temperature sensor element 407.

The mount base 11Z and the temperature sensor element 407 are joined to each other to hermetically seal the recess R1 and to electrically connect the two element terminals 407b of the temperature sensor element 407 and two terminals 3 of the mount base 11Z. To the joining for sealing, the explanation of joining the lid 13 and the mount base 11 in the first embodiment may be applied. To the joining for electrical connection, the explanation of joining the temperature sensor element 7 and the mount base 11 in the first embodiment may be applied. In this case, the words “outer electrode 7b” in the first embodiment may be replaced with the words “element terminal 407b”.

As mentioned in the description of the first embodiment, when a sealing material 33 is conductive, the sealing material 33 may be, for example, away from two connection electrodes 31 or may be connected to one of the two connection electrodes 31 (in the illustrated example, the connection electrode 31 on the +D1 side) on a frame-portion upper surface 23e. The example in FIG. 9 illustrates the latter.

The two connection electrodes 31 are electrically connected to two terminals 3 with two pieces of wiring 27 interposed therebetween. It has already been mentioned that the wiring 27 may have various configurations. In the example in FIG. 11, A piece of wiring 27 connecting the connection electrode 31 and a terminal 3 located on the side (on the +D1 side) opposite to pads 25 in the longitudinal direction of the mount base 11 includes only a via conductor extending through the frame portion 23b and a substrate portion 23a. The connection electrode 31 located on the pad 25 side (the −D1 side) includes a via conductor extending through the frame portion 23b, a conductor layer located on the lower surface of the frame portion 23b, and a via conductor (not illustrated) extending through the substrate portion 23a.

### 4.2. Other Examples According to Fourth Embodiment

### 4.2.1. Other Examples of Connection Electrodes

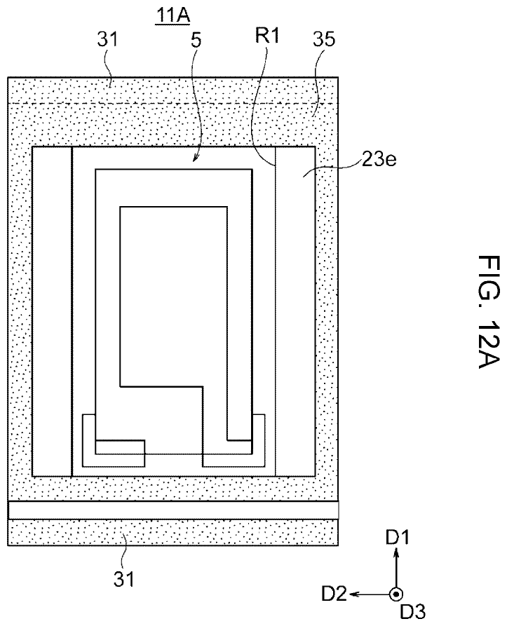

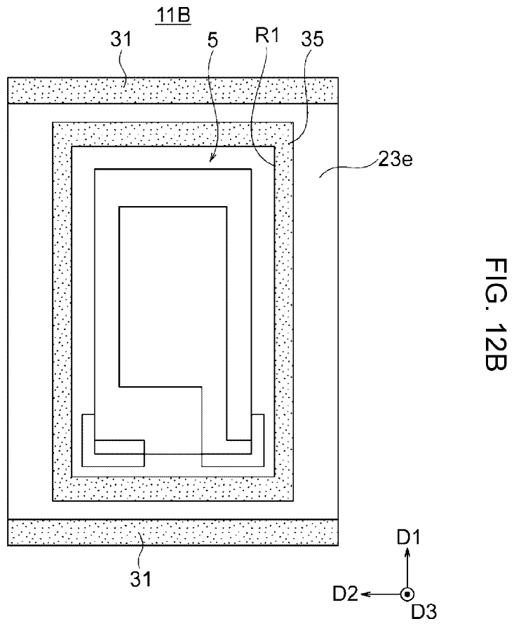

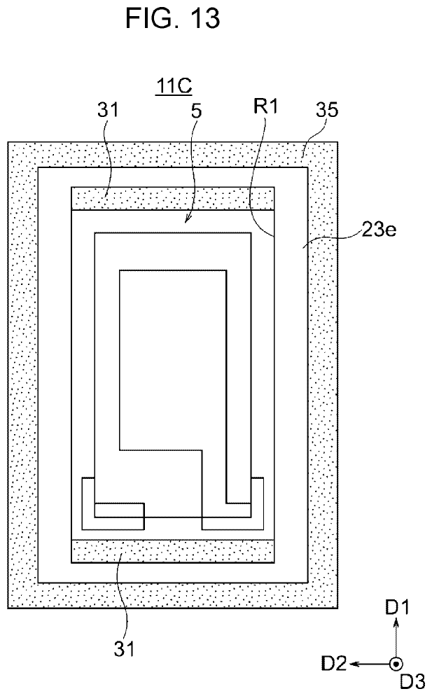

FIGS. 12A, 12B, and 13 are plan views of mount bases 11A, 11B, and 11C according to other examples. These figures also illustrate a quartz crystal element 5.

As already mentioned, the positions, shapes, and dimensions of the connection electrodes 31 (in another viewpoint, the element terminals 407b) are not particularly limited. FIGS. 12A, 12B, and 13 illustrate examples in which the positions, shapes, and dimensions of connection electrodes 31 differ from those illustrated in FIGS. 9 to 11 as examples. A specific description is as follows. Note that although not illustrated, the positions, shapes, and dimensions of element terminals 407b connected to the connection electrodes 31 according to other examples are approximately the same as or similar to those of the connection electrodes 31 according to these other examples.

In the example illustrated in FIG. 12A, contrary to the embodiment, two connection electrodes 31 are located outside a first metal layer 35 (in another viewpoint, a sealing material 33). However, one connection electrode 31 (the connection electrode 31 on the +D1 side) is connected to the first metal layer 35. In this case, as already mentioned, the one connection electrode 31 and the first metal layer 35 may be composed of different materials or may be integrally formed by using the same material.

The explanation of the positions, shapes, and dimensions of the connection electrodes 31, the element terminals 407b, and the sealing material 33 (the first metal layer 35 and/or a second metal layer 37) in the embodiment (for example, refer to the explanation in the first embodiment applied to the fourth embodiment (the same or a similar explanation applies in the following)) may be applied to the example illustrated in FIG. 12A unless a contradiction or the like occurs. In this case, word replacement such as replacing the words “inner edge” with the words “outer edge” as appropriate may be performed rationally.

For example, in the description of the embodiments, it was mentioned that all of the outer edges of the sealing material 33 may be aligned with the outer edges of the frame-portion upper surface 23e, or part or all of the outer edges of the sealing material 33 may be away from the outer edges of the frame-portion upper surface 23e. In the example in FIG. 12A, all of the inner edges of the sealing material 33 may be aligned with the inner edge of the frame-portion upper surface 23e, or part or all of the inner edges of the sealing material 33 may be away from the inner edges of the frame-portion upper surface 23e.

For example, in the description of the embodiments, it was mentioned that the inner edge of the sealing material 33 is away from the inner edge of the frame-portion upper surface 23e at least in the region where the connection electrodes 31 are located (excluding the portion where one connection electrode 31 can be considered to be part of the first metal layer 35). In the example in FIG. 12A, the outer edge of the sealing material 33 is away from the outer edge of the frame-portion upper surface 23e at least in the region where the connection electrode 31 is located (however, excluding the portion where one connection electrode 31 can be considered to be part of the first metal layer 35).

In the example in FIG. 12A, the inner edges of the first metal layer 35 (the sealing material 33) are aligned with the inner edges of the frame-portion upper surface 23e on the sides (in the illustrated example, the short sides) where the connection electrodes 31 are located. On the sides where the connection electrodes 31 are not located (in the illustrated example, the long sides), the outer edges of the first metal layer 35 (the sealing material 33) are aligned with the outer edges of the frame-portion upper surface 23e, and the first metal layer 35 (the sealing material 33) has widths smaller than those of the frame-portion upper surface 23e. As can be clearly understood from the explanation above, the position and width of the first metal layer 35 (the sealing material 33) are not limited to the illustrated configuration. For example, the first metal layer 35 (the sealing material 33) may have widths equivalent to the widths of the frame-portion upper surface 23e on the sides where the connection electrodes 31 are not located.

In the example illustrated in FIG. 12B, two connection electrodes 31, as in the example illustrated in FIG. 12A, are located outside a first metal layer 35. However, each of the connection electrodes 31 is away from the first metal layer 35. Also to the example in FIG. 12B, the explanation of the positions, shapes, and dimensions of the connection electrodes 31, the element terminals 407b, the sealing material 33 (the first metal layer 35 and/or the second metal layer 37) in the embodiment may be applied, as in the example in FIG. 12A, for example, by replacing “inner edge” with “outer edge”.

In the example in FIG. 12B, on the sides where the connection electrodes 31 are located (in the illustrated example, the short sides), the inner edges of the first metal layer 35 (the sealing material 33) are aligned with the inner edges of a frame-portion upper surface 23e, as in the example in FIG. 12A. On the sides where the connection electrodes 31 are not located (in the illustrated example, the long sides), the first metal layer 35 (the sealing material 33) has widths smaller than those of the frame-portion upper surface 23e, as in FIG. 12A. However, unlike the example in FIG. 12A, the inner edges of the first metal layer 35 (the sealing material 33) are aligned with the inner edges of the frame-portion upper surface 23e. As can be clearly understood from the explanation above, the position and width of the first metal layer 35 (the sealing material 33) are not limited to the illustrated configuration. For example, the first metal layer 35 (the sealing material 33) may have widths equivalent to those of the frame-portion upper surface 23e on the sides where the connection electrodes 31 are not located.

In the example illustrated in FIG. 13, two connection electrodes 31, as in the example illustrated in FIGS. 9 to 11, are located inside a first metal layer 35. However, each of the connection electrodes 31 is away from the first metal layer 35.

Although not illustrated, a configuration in which one of the connection electrodes 31 is located inside the first metal layer 35, and the other one of the connection electrodes 31 is located outside the first metal layer 35 is possible.

FIGS. 9 to 11 illustrate, as an example, a configuration in which one connection electrode 31 is connected to the first metal layer 35, and either of the two element terminals 407b is not connected to the second metal layer 37. However, also the one element terminal 407b joined to the one connection electrodes 31 connected to the first metal layer 35 may be connected to the second metal layer 37. Contrary to the illustrated example, a configuration in which either of the two connection electrodes 31 is not connected to the first metal layer 35, and one element terminal 407b is connected to the second metal layer 37 is possible. in addition, a configuration in which either of the two connection electrodes 31 is not connected to the first metal layer 35, and either of the two element terminals 407b is not connected to the second metal layer 37 is possible. The explanation above may hold in the configuration in which at least one of the connection electrodes 31 is located inside the sealing material 33 and the configuration in which at least one of the connection electrodes 31 is located outside the sealing material 33.

### 4.2.2. Other Examples of Element Body

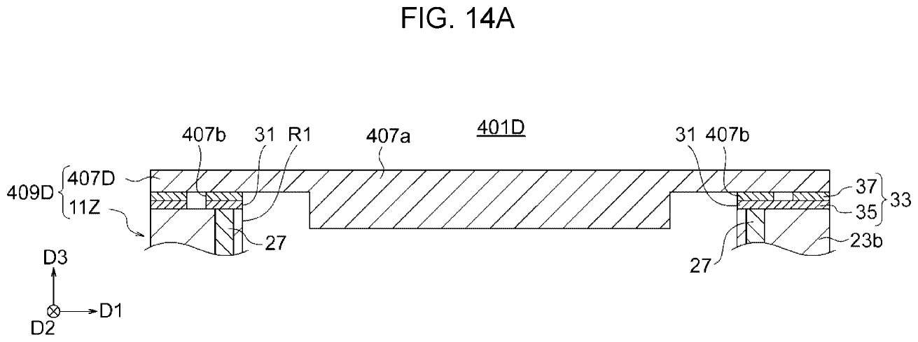

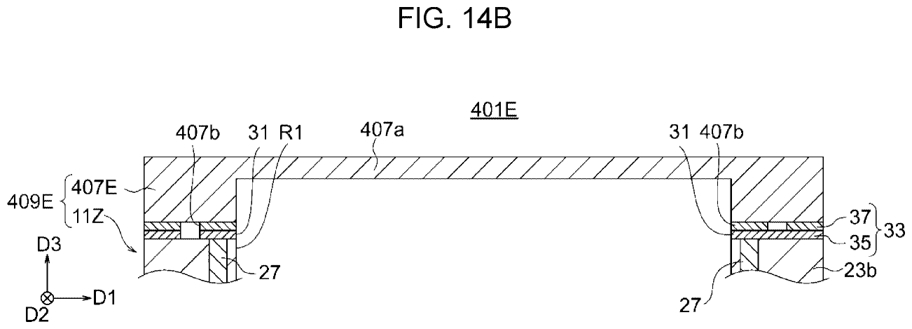

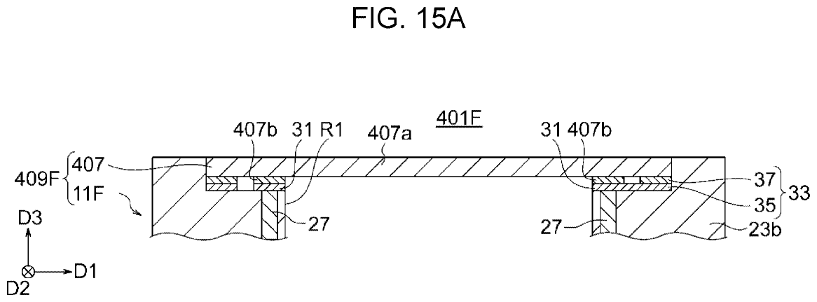

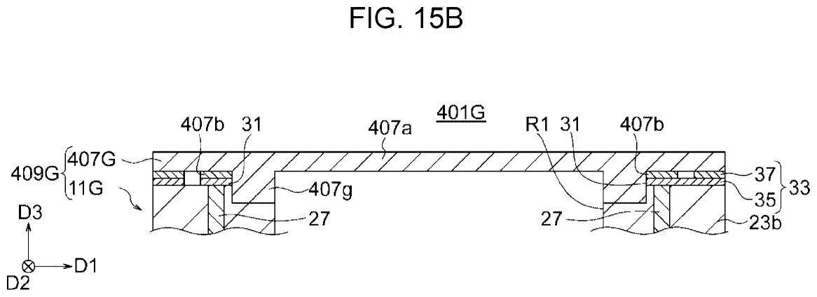

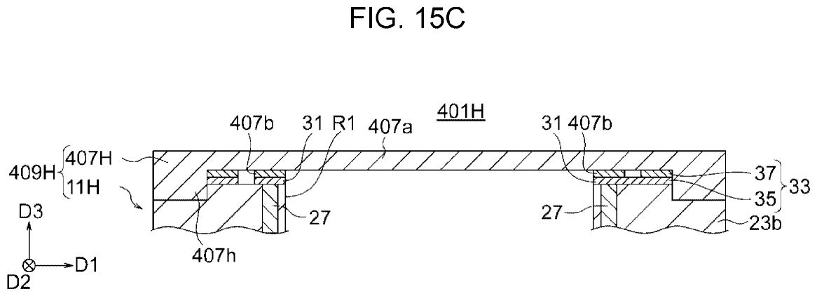

FIGS. 14A, 14B, 15A, 15B, and 15C are cross-sectional partial views of quartz crystal resonators 401D, 401E, 401F, 401G, and 401H according to other examples. These views correspond to an upper portion of FIG. 11. Note that in these drawings, the locations of connection electrodes 31 and the like in plan view are based on the example of those in the embodiment. However, the locations of the connection electrodes 31 and the like in plan view may be based on the examples described with reference to FIGS. 12A to 13.

In the example illustrated in FIG. 14A, a temperature sensor element 407D (an element body 407a) has a shape other than a flat plate shape. Specifically, as for the temperature sensor element 407D, the region facing the recess R1 is thicker than the other region so as to protrude toward the recess R1. This configuration, for example, enables a sufficient volume to be allocated to the element body 407a at a position near the quartz crystal element 5 or enables the element body 407a to be located closer to the quartz crystal element 5. In another viewpoint, since the region overlapping a frame-portion upper surface 23e of the element body 407a is thin, the thickness of a package 409D can be reduced.

The size and thickness of the thicker region of the temperature sensor element 407D are not particularly limited. In the illustrated example, the thicker region is smaller than the recess R1 in plan view and is located in a center region of the recess R1. Hence, the thicker region is away from the inner peripheral surfaces of the recess R1. However, the thicker region may have a size equivalent to that of the recess R1 or may have a length equivalent to that of the recess R1 in any direction so that the thicker region can fit into the recess R1. The thickness of the thicker region may be, for example, 1.2 times or more, 1.5 times or more, or 2 times or more the thickness of the region overlapping the frame-portion upper surface 23e. Unless the temperature sensor element 407D comes into contact with the quartz crystal element 5, the upper limit is not particularly limited.

In the example illustrated in FIG. 14B a temperature sensor element 407E (an element body 407a) has a shape other than a flat plate shape, as in the example in FIG. 14A. However, in the temperature sensor element 407E, contrary to the example in FIG. 14A, the region (a frame-shaped region) overlapping the frame-portion upper surface 23e is thicker than the other region so as to protrude toward the frame-portion upper surface 23e. This configuration, for example, enables the temperature sensor element 407E to have a sufficient strength. This configuration also enables the capacity of the space inside a package 409E to be larger than in the configuration in which the entire temperature sensor element 407E is thick.

In the temperature sensor element 407E, the size of the thicker region may be equivalent to the size of the frame-portion upper surface 23e as in the illustrated example, or the thicker region may extend toward the center of the recess R1. In this case, for example, the inner edges of the thicker region may be outside the outer edges of the quartz crystal element 5 in transparent plan view. The thickness of the thicker region of the temperature sensor element 407E is not particularly limited. For example, the thickness of the thicker region may be 1.2 times or more, 1.5 times or more, or 2 times or more the thickness of the region facing the recess R1. The upper limit is not particularly limited.

In the example in FIGS. 9 to 11, 14A, and 14B, the temperature sensor element (407 or the like) is not in contact with the mount base 11Z in the directions parallel to the bottom surface of the recess R1 (the directions parallel to the D1-D2 plane). For example, the temperature sensor element (407 or the like) is not in contact with the outer peripheral surfaces of the mount base 11Z in the recess R1. In contrast, the configurations illustrated in FIGS. 15A to 15C are examples of configurations in which a temperature sensor element (407 or the like) is in contact with a mount base (11F or the like) in the directions parallel to the D1-D2 plane. A specific description is as follows.

In a package 409F illustrated in FIG. 15A, a temperature sensor element 407 has a size within the outer edges of a frame portion 23b in plan view. The region facing the temperature sensor element 407 in the upper surface of the frame portion 23b is lower than the outside region (a frame-shaped region). The temperature sensor element 407 fits into an inside of the upper end of the frame portion 23b (the upper end of the recess R1). Joining for sealing and joining for electrical connection between the temperature sensor element 407 and a mount base 11F may be achieved, for example, in the region where the temperature sensor element 407 overlaps the upper surface of the frame portion 23b, as in the first embodiment.

In the frame portion 23b, the width (the length from the inner edge to the outer edge) of the lower region and the width of the higher region are not particularly limited. For example, these two widths may be equivalent to each other, or one of them may be larger than the other. In the frame portion 23b, the height difference between the lower region and the higher region is also not particularly limited. In connection with the height difference between these regions, for example, the height (the position in the D3 direction) of an upper surface of the temperature sensor element 407 may be lower than, equivalent (the illustrated example) to, or higher than the height (the position in the D3 direction) of the higher region of the frame portion 23b.

Note that as for the frame portion 23b, the method of making the first region of the upper surface lower than the second region is not particularly limited. For example, as in the formation of the recess R1, a ceramic green sheet may be stacked on the second region to make the second region relatively high, or the first region may be made relatively low by press working. The first region may be made relatively low by performing polishing, grinding, cutting, or laser processing on the first region. The same as or a similar explanation applies in other examples.

In a package 409G illustrated in FIG. 15B, a region on the inner-edge side (a frame-shaped region) on the upper surface of the frame portion 23b is lower than a region on the outer-edge side. A temperature sensor element 407G includes a protrusion 407g located in a region facing the region on the inner-edge side mentioned above (the frame-shaped region) and protruding toward the frame portion 23b side. The protrusion 407g is fitted into an inner region of the upper end of the frame portion 23b (the upper end of the recess R1).

The width (the length from the inner edge to the outer edge) and the height (the length in the D3 direction) of the protrusion 407g are not particularly limited. For example, the width of the protrusion 407g may be smaller than, equivalent to, or larger than or equal to ½ of the width of the frame portion 23b. The height of the protrusion 407g may be smaller than, equivalent to, or larger than the thickness of the region of the temperature sensor element 407 other than the region where the protrusion 407g is located. The explanation in this paragraph may be applied to a protrusion 407h (FIG. 7C) described later.

In the example in FIG. 15B, joining for sealing and joining for electrical connection between the temperature sensor element 407G and a mount base 11G are achieved, for example, in the region outside the protrusion 407g. However, at least one of joining for sealing and joining for electrical connection may be achieved on the protrusion 407g.

In a package 409H illustrated in FIG. 15C, contrary to the example in FIG. 15B, a region on the outer-edge side (a frame-shaped region) of the upper surface of the frame portion 23b is lower than a region on the inner-edge side. A temperature sensor element 407H includes a protrusion 407h located in a region facing the region on the outer-edge side mentioned above (the frame-shaped region) and protruding toward the frame portion 23b side. The protrusion 407h surrounds the upper end of the frame portion 23b.

In the example in FIG. 15C, joining for sealing and joining for electrical connection between the temperature sensor element 407H and a mount base 11H are achieved, for example, in the region inside the protrusion 407h. However, at least one of joining for sealing and joining for electrical connection may be achieved on the protrusion 407h.

In FIGS. 15A to 15C, joining for sealing and joining for electrical connection are achieved in a region facing in the +D3 direction out of the upper surface of the frame portion 23b. However, instead of or in addition to such joining, joining for sealing and/or joining for electrical connection may be achieved in a region facing the inner peripheral side or the outer peripheral side of the step out of the upper surface of the frame portion 23b.

The embodiment and other examples described above may be combined as appropriate. For example, the configuration in FIG. 14A in which one region (for example, a region away from the inner peripheral surfaces of the recess R1) of the temperature sensor element 407D is thicker may be combined with the examples in FIGS. 15A, 15B, and 15C.

### 4.3. Summary of Fourth Embodiment

As described above, the piezoelectric device (the quartz crystal resonator 401) includes the piezoelectric element (the quartz crystal element 5), the mount base 11 (which symbol is sometimes used as a representative of 11Z and the like), and the temperature sensor element 407. The temperature sensor element 407 includes a portion (in the illustrated example, the entire temperature sensor element 407) located closer to the upper end of the recess R1 than the quartz crystal element 5. Accordingly, for example, as already mentioned, this reduces the probability that the temperature sensor element 207 can be excessively affected by the heat from the bottom surface of the recess R1. Hence, the measured temperature is likely to follow the temperature of the quartz crystal element 5.

The temperature sensor element 407 may hermetically seal the recess R1.

This is advantageous, for example, to downsizing the vibrator 401. It also provides effects the same as or similar to those in the first embodiment. For example, when a quartz crystal element 5 and the mount base 11 are determined to be defective in an inspection before sealing, the temperature sensor element 407 will not be wasted. In addition, for example, the temperature sensor element 407 will not be trimmed with laser light.

The temperature sensor element 407 need not be in contact with the mount base 11 in the directions parallel to the bottom surface of the recess R1 (the directions parallel to the D1-D2 plane) (see FIGS. 9 to 11, 14A, and 14B). For example, the temperature sensor element (407 or the like) is not in contact with the outer peripheral surfaces of the mount base 11 in the recess R1.

In this case, for example, when a region surrounding the temperature sensor element 407 is joined to the frame portion 23b of the mount base 11, some positional deviation of the two components relative to each other is allowed in the directions parallel to the D1-D2 plane. This is likely to reduce thermal stress generated between the temperature sensor element 407 and the mount base 11.

The temperature sensor element 407 may include a portion fitted into the upper end of the recess R1 (see FIGS. 15A and 15B).

In this case, for example, the accuracy in positioning the temperature sensor element 407 relative to the mount base 11 is improved. This, for example, reduces the probability of occurrence of an unintended short circuit between the element terminals 407b and a conductive sealing material 33. In addition, for example, the accuracy in positioning of the element body 407a relative to the quartz crystal element 5 is improved, which in turn improves the accuracy of measured temperature. In addition, for example, since the boundary surface between the temperature sensor element 407 and the mount base 11 is not planar and has flexed portions in cross-sectional view, it increases the sealing performance. In addition, for example, as mentioned in the explanation of FIG. 14A, when the entire region overlapping the recess R1 of the temperature sensor element 407D is made thicker, and the temperature sensor element 407D is fitted into the upper end of the recess R1, it provides effects such as making it easier to allocate a sufficient volume to the temperature sensor element 407D.

The temperature sensor element 407 may include a portion surrounding an outer peripheral side of the upper end of the mount base 11 (see FIG. 15C).

In this case, for example, as in the configuration mentioned above in which the temperature sensor element 407 includes a portion fitted into the upper end of the recess R1, the accuracy in positioning the temperature sensor element 407 relative to the mount base 11 is improved. In addition, since the boundary surface between the temperature sensor element 407 and the mount base 11 has flexed portions, it increases the sealing performance. In addition, for example, since the strength of the edge portions of the temperature sensor element 407 is increased, it reduces the probability of occurrence of a crack at an edge portion.

The temperature sensor element 407 may include the element body 407a and the two element terminals 407b exposed to the outside of the element body 407a. The mount base 11 may include the substrate portion 23a, the frame portion 23b, and the two connection electrodes 31. The substrate portion 23a may include the bottom surface of the recess R1. The frame portion 23b may include the inner peripheral surfaces of the recess R1. The two connection electrodes 31 may be located on the upper end of the frame portion 23b and may be joined to the two element terminals 407b. The element body 407a and the upper end of the frame portion 23b may be joined to each other in the sealing region (the region where the sealing material 33 is located) extending annularly along the upper end of the frame portion 23b. At least one of the two connection electrodes 31 may be located on the inner peripheral side of the sealing region (the sealing material 33) mentioned above (see FIGS. 9 to 11 and 13).

In this case, for example, the connection electrode 31 located on the inner peripheral side of the sealing material 33 is in the sealed space and protected together with the quartz crystal element 5. Hence, for example, the durability of the vibrator 401 is improved. In addition, for example, since joining between the element terminals 407b and the connection electrodes 31 and joining for sealing are both achieved on the upper surface of the frame portion 23b, both processes can be performed together.

At least one of the two connection electrodes 31 may be located on the outer peripheral side of the sealing region (the sealing material 33) mentioned above (see FIGS. 12A and 12B).

In this case, for example, the element terminals 407b can be easily located at end portions of the element body 407a. A typical temperature sensor element has element terminals on both ends. Hence, a commercially available temperature sensor element can be used as the temperature sensor element 407, or a design change from a conventional temperature sensor element to the temperature sensor element 407 can be saved.

The mount base 11 may include the first metal layer 35. The first metal layer 35 may be located on the upper end of the frame portion 23b, may have an annular shape extending along the upper end of the frame portion 23b, and may be joined to the element body 407a (directly or indirectly with the second metal layer 37 interposed therebetween) for sealing. One of the two connection electrodes 31 may be connected to the first metal layer 35 on the upper end of the frame portion 23b.

In this case, for example, a sufficient area can be easily allocated to the first metal layer 35 and/or the connection electrode 31 connected to the first metal layer 35. Note that the configuration in which one connection electrode 31 is connected to the first metal layer 35 may include the configuration in which one connection electrode 31 is included in the first metal layer 35.

### 5. Specific Examples of Wiring in Package

As mentioned above, the positions of the pads 25 and the connection electrodes 31 in plan view are not particularly limited, and the positional relationship in plan view between the terminals 3 connected to the pads 25 and the terminals 3 connected to the connection electrodes 31 is also not particularly limited. The wiring 27 may have various configurations depending on the positions of the pads 25, the connection electrodes 31, and the terminals 3. Also when the pads 25, the connection electrodes 31, and the terminals 3 have specified positions, the wiring 27 may have various configurations. The following illustrates specific examples of the configuration of the wiring 27 when the pads 25, the connection electrodes 31, and the terminals 3 have specified positions. Note that in the drawings referred to in the following description, via conductors that are hidden by a layer-shaped conductor and cannot be seen are sometimes depicted with solid lines instead of dotted lines for convenience.

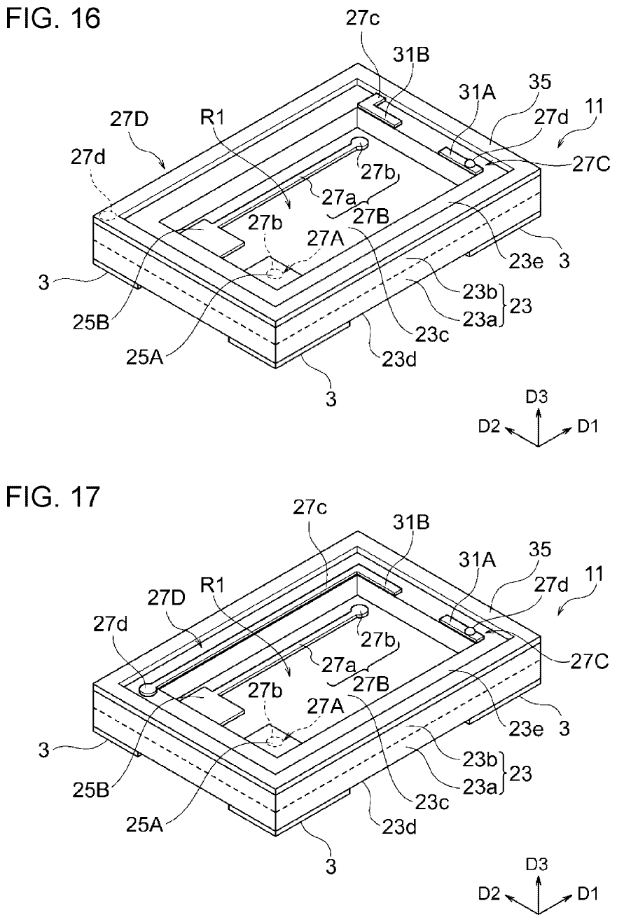

FIG. 16 is a perspective view of a specific example of the wiring 27. This figure corresponds to part of FIG. 1.

In the example in FIG. 16, the two terminals 3 connected to two pads 25 are located at two diagonal corners of a second substrate surface 23d, and the two terminals 3 connected to two connection electrodes 31 are located at the other two diagonal corners. In the example in FIG. 16, as in the example in FIG. 1, the two pads 25 are located on one side (the −D1 side) of a first substrate surface 23c in the longitudinal direction and side by side in the lateral direction (the D2 direction). The two connection electrodes 31 are located on the other side (the +D1 side) of the first substrate surface 23c in the longitudinal direction and side by side in the lateral direction (the D2 direction).

Wiring 27A connecting a terminal 3 and one (a pad 25A on the −D1 side and on the −D2 side in the example in FIG. 16) of the two pads 25 includes a via conductor 27b extending through a substrate portion 23a in the thickness direction. The via conductor 27b has one end connected to the pad 25A and the other end connected to the terminal 3 located on the −D1 side and on the −D2 side. Wiring 27B connecting a terminal 3 and the other (a pad 25B on the −D1 side and on the +D2 side in the example in FIG. 16) of the two pads 25 includes a layer-shaped conductor 27a extending from the pad 25B toward the other side (the +D1 side) in the longitudinal direction and a via conductor 27b located at a position overlapping the layer-shaped conductor 27a and extending through the substrate portion 23a in the thickness direction. The layer-shaped conductor 27a is stacked on the first substrate surface 23c. The via conductor 27b has one end connected to the layer-shaped conductor 27a and the other end connected to the terminal 3 located on the +D1 side and on the +D2 side. With these two pieces of wiring 27, the two pads 25 are connected to terminals 3 located at two diagonal corners.

Wiring 27C connecting a terminal 3 and one (a connection electrode 31A on the +D1 side and on the −D2 side in the example in FIG. 16) of the two connection electrodes 31 includes a via conductor 27d extending through the substrate portion 23a and a frame portion 23b in the thickness direction. This via conductor 27d has one end connected to the connection electrode 31A and the other end connected to the terminal 3 located on the +D1 side and on the −D2 side. Wiring 27D connecting a terminal 3 and the other (a connection electrode 31B on the +D1 side and on the +D2 side in the example in FIG. 16) of the two connection electrodes 31 includes a layer-shaped conductor 27c extending from the connection electrode 31 to a first metal layer 35 (in another viewpoint, a sealing material 33 (the same or a similar explanation applies in the following description of FIGS. 16 to 18 unless a contradiction or the like occurs)), the first metal layer 35, and a via conductor 27d located at a position overlapping the first metal layer 35 and extending through the substrate portion 23a and the frame portion 23b in the thickness direction. The layer-shaped conductor 27c is stacked on the frame-portion upper surface 23e. The via conductor 27d has one end connected to the first metal layer 35 and the other end connected to the terminal 3 located on the −D1 side and on the +D2 side. With these two pieces of wiring 27, the two connection electrodes 31 are connected to terminals 3 located at two diagonal corners.

Note that part or all of the layer-shaped conductor 27a of the wiring 27B may overlap the frame portion 23b (may be located between the substrate portion 23a and the frame portion 23b). The extending direction, shape, and the like of the layer-shaped conductor 27c of the wiring 27D are not particularly limited. In the example in FIG. 16, the layer-shaped conductor 27c extends in the +D1 direction (toward a short side of an outer edge of the frame portion 23b). Unlike the illustrated example, the layer-shaped conductor 27c may extend, for example, in the +D2 direction (toward a long side of an outer edge of the frame portion 23b). The layer-shaped conductor 27c may have a length the same as that of the connection electrode 31 in the D2 direction and extends in the +D1 direction. The material and/or thickness of the layer-shaped conductor 27c may be the same as, or different from, those of the connection electrode 31 and/or the first metal layer 35. In a viewpoint of material, thickness, planar shape, and the like, the layer-shaped conductor 27c need not be clearly distinguished from the connection electrode 31 and/or the first metal layer 35. In addition to or instead of the via conductor 27d of the wiring 27D, a layer-shaped conductor located on an inner surface of a castellation may be used.

The terminal 3 connected to the connection electrode 31B may be, for example, one to which the reference electric potential is applied. When the recess R1 of the mount base 11 in FIG. 16 is closed with a conductive lid 13 (which, in other words, is not the temperature sensor element 407 in the fourth embodiment), the first metal layer 35 may contribute to applying the reference electric potential to the lid 13 through the second metal layer 37. As a matter of course, as already mentioned above, the lid 13 may be non-conductive, and the reference electric potential being applied to the lid 13 is not essential. An electric potential other than the reference electric potential may be applied to the connection electrode 31B.

FIG. 17 is a perspective view of another specific example of wiring 27. FIG. 17 is similar to FIG. 16.

The example in FIG. 17 differs from the example in FIG. 16 only in the configuration of wiring 27D. The wiring 27D does not include the first metal layer 35. In another viewpoint, the connection electrode 31B is not electrically connected to the first metal layer 35. Specifically, the wiring 27D includes a layer-shaped conductor 27c extending from the connection electrode 31B in the −D1 direction and a via conductor 27d overlapping the layer-shaped conductor 27c. The via conductor 27d has one end connected to the layer-shaped conductor 27c and the other end connected to the terminal 3 located on the −D1 side and on the +D2 side.

With the specific examples of the wiring 27 in FIGS. 16 and 17, for example, the wiring 27 with changing electric potential can be easily located inside the sealing material 33 in plan view. This, for example, makes it easier to locate the wiring 27 in the sealed space and to electromagnetically shield the wiring 27.

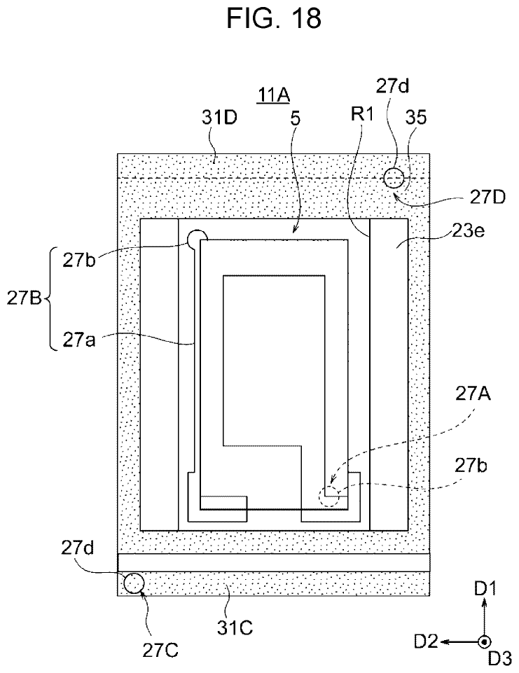

FIG. 18 is a plan view of still another specific example of the wiring 27. FIG. 18 is similar to FIG. 12A.

Also in the example in FIG. 18, as in the example in FIG. 16, the two terminals 3 connected to two pads 25 are located at two diagonal corners of the second substrate surface 23d, and the two terminals 3 connected to two connection electrodes 31 are located at the other two diagonal corners. The positions of the two pads 25 and the two connection electrodes 31 are as described with reference to FIG. 12A and other figures. The example in FIG. 18, wiring 27A and wiring 27B are the same as or similar to the wiring in the example in FIG. 16.

Wiring 27C connecting a terminal 3 and one (a connection electrode 31C located on the −D1 side in the example in FIG. 18) of the two connection electrodes 31 includes a via conductor 27d extending through a substrate portion 23a and a frame portion 23b in the thickness direction. This via conductor 27d has one end connected to the connection electrode 31C and the other end connected to the terminal 3 located on the −D1 side and on the +D2 side. Wiring 27D connecting a terminal 3 and the other (a connection electrode 31D located on the +D1 side in the example in FIG. 18) of the two connection electrodes 31 includes a via conductor 27d extending through the substrate portion 23a and the frame portion 23b in the thickness direction. This via conductor 27d has one end connected to the connection electrode 31D and the other end connected to the terminal 3 located on the +D1 side and on the −D2 side. With these two pieces of wiring 27, the two connection electrodes 31 are connected to terminals 3 located at two diagonal corners.

Note that in the example in FIG. 18, the connection electrode 31D and the first metal layer 35 are connected. Hence, an upper end of the via conductor 27d of the wiring 27D may be connected to the first metal layer 35 in addition to the connection electrode 31D (the illustrated example), may be connected to only the connection electrode 31D, or may be connected to only the first metal layer 35. In addition to or instead of the via conductor 27d of the wiring 27C and/or 27D, a layer-shaped conductor located on an inner surface of a castellation may be used. The terminal 3 connected to the connection electrode 31D may be, for example, one to which the reference electric potential is applied. As a matter of course, as already mentioned above, an electric potential other than the reference electric potential may be applied to the connection electrode 31D.

The specific example of the wiring 27 in FIG. 18, for example, makes it easier to avoid a situation in which pieces of wiring 27 having different electric potentials intersect each other. This reduces electrical interference between the pieces of wiring 27. This in turn improves characteristics of the vibrator.

### 6. Application Example of Quartz Crystal Resonator

FIG. 19 is a schematic diagram illustrating an application example of the quartz crystal vibrator 1. Note that although symbols in the first embodiment are used for convenience, the explanation here may be applied to the other embodiments.

As the cross-sectional view in the lower part of FIG. 19 indicates, the vibrator 1 is, for example, mounted on the circuit substrate 53 in use. More specifically, as already mentioned, the terminals 3 and pads (not illustrated) located on an upper surface of the circuit substrate 53 and facing the terminals 3 are joined with a conductive joining material (the symbol of which is omitted) between the terminals 3 and the pads. Note that the vibrator 1 may be mounted on a base other than the circuit substrate 53. For example, the vibrator 1 may be mounted on a base having a shape departing from the concept of a substrate (for example, a base as part of a package). Note that in the explanation here, the words “circuit substrate 53” may be replaced with the word “base” having an upper level concept of the circuit substrate 53, unless a contradiction or the like occurs.

The vibrator 1 mounted on the circuit substrate 53 may be sealed with an insulating sealing material 55 (the illustrated example) but is not limited to this configuration. Examples of the material of the sealing material 55 include a resin. The resin may contain insulating (or conductive) fillers. The physical properties of the sealing material 55 (for example, the heat insulation property and the stiffness) may be determined as appropriate. The sealing material 55 covers, for example, an upper surface and side surfaces of the vibrator 1 and is joined to the upper surface of the circuit substrate 53. The sealing material 55 may be interposed, but is not limited to being interposed, between the vibrator 1 and the circuit substrate 53. Unlike the illustrated example, a configuration in which the sealing material 55 does not cover the upper surface of the vibrator 1 is possible. The sealing material 55 may seal another electronic component mounted on the circuit substrate 53, together with the vibrator 1.

The circuit substrate 53, for example, includes a wiring board (for example, a printed circuit board) and one or more electronic elements mounted on or integrated in the wiring board. Examples of the electronic elements include an integrated circuit (IC) element, a capacitor, an inductor, and a resistor. As the upper part of FIG. 19 indicates, the circuit substrate 53 includes various circuits (53a to 53d) each including one or more electronic elements. Note that although the word “circuit” is used here for convenience, part or all of the various circuits may be implemented by a processor executing a program. The circuits included in the circuit substrate 53 are, for example, as follows.

An oscillation circuit 53a applies an alternating current to the quartz crystal element 5 and generates an oscillation signal. A temperature compensation circuit 53b (which is abbreviated as “compensation circuit” in FIG. 19) inputs a signal according to the detection temperature detected by the temperature sensor element 7 to the oscillation circuit 53a to compensate for changes in the frequency characteristics of the quartz crystal element 5 due to temperature. More specifically, the temperature sensor element 7 outputs an analog signal having a signal level (for example, voltage or current) according to temperature. An A/D circuit 53d converts the analog signal from the temperature sensor element 7 into a digital signal and outputs the resultant signal. A conversion circuit 53c converts the value of the digital signal from the A/D circuit 53d into a temperature and outputs the resultant signal to the compensation circuit 53b. Note that the combination of the vibrator 1 and the circuit substrate 53 (in another viewpoint, at least the oscillation circuit 53a out of the circuits included in the circuit substrate 53) may be considered to be an oscillator 53.

Each of the quartz crystal resonators 1, 1C, 1D, 1E, 201, 301, 401, 401D, 401E, 401F, 401G, and 401H in the embodiments and other examples described above is an example of a piezoelectric device. The quartz crystal element 5 is an example of a piezoelectric element.

The technology according to the present disclosure is not limited to the embodiments described above and may be implemented in various configurations.

The piezoelectric material is not limited to quartz crystal. For example, the piezoelectric material may be another single crystal material or a polycrystalline material (for example, a ceramic). Note that quartz crystal containing an appropriate dopant is considered to be a kind of quartz crystal.

The piezoelectric device is not limited to a quartz crystal resonator (piezoelectric vibrator). For example, the piezoelectric device may be, in addition to a piezoelectric element (for example, a quartz crystal element), an oscillator including an integrated circuit (IC) element that applies a voltage to the piezoelectric element and generate an oscillation signal. The piezoelectric device may be one not contributing to generation of an oscillation signal. For example, the piezoelectric device may be a gyro sensor. The piezoelectric device may include electronic elements in addition to a piezoelectric element, a temperature sensor element, and an IC.

As can be understood from the above description, the number of pads (for example, the pads 25 and the connection electrodes 31) and the number of external terminals (for example, the terminals 3) included in a piezoelectric device are not particularly limited. The connection relationship between the plurality of pads and the plurality of external terminals is also not particularly limited. For example, in an oscillator, a piezoelectric element and a temperature sensor element may be electrically connected to an IC, not to external terminals of the piezoelectric device.

In a piezoelectric device, the structure of the package housing a piezoelectric element may have an appropriate configuration. For example, a package may have an H-shaped cross section having recesses in upper and lower faces. In this case, for example, the aforementioned IC may be mounted in the recess on the lower face. A package may include a temperature-controlled chamber. A piezoelectric device is not limited to ones of surface-mounting types and may be, for example, one of a through-hole mounting type. Whether a piezoelectric device is of a surface-mounting type or not, external terminals of the package (the terminals 3 in the embodiments) are not limited to layer-shaped ones and may be, for example, pin-shaped.

The mounting mode of a piezoelectric element to a mount base is not particularly limited. For example, a piezoelectric element may be supported at both ends with two pieces of a conductive joining material joined to two extension electrodes. Alternatively, for example, in a piezoelectric element, a conductive joining material may be joined to one extension electrode, and a bonding wire may be joined to one extension electrode. As a joining material for supporting one end or both ends of an piezoelectric element, an insulating (which can be conductive) joining material joined to a region other than the regions of extension electrodes may be used.

As other examples of the fourth embodiment, the configurations in which at least one of the connection electrodes 31 (in another viewpoint, the element terminals 407b) is located outside the sealing material 33 are illustrated (FIGS. 12A, 12B, and 18). Also in the first embodiment, at least one of the two outer electrodes 7b may be located outside the sealing material 33. It can be clearly understood that such a configuration is possible, for example, from the configuration in which the sealing material 33C in FIG. 5A is joined to the lid 13 with the temperature sensor film 7a interposed therebetween. When the lid lower surface 13b and the sealing material 33 are insulating, a configuration in which only the outer electrode 7b (or a relay conductor connecting the outer electrode 7b and the functional portion) extends from the inside of the sealing material 33 to the outside of the sealing material 33 is possible.

As in the third embodiment (FIG. 8), the temperature sensor element located at a wall portion of the recess may be one including a temperature sensor film as in the first embodiment. Even in this case, since the temperature sensor film includes a portion located closer to the lid than the piezoelectric element, for example, the effects that the temperature on the bottom surface side of the recess exerts on the measured temperature are reduced. Such a temperature sensor film may be stacked on the inner peripheral surface of a wall portion of the recess or may be stacked on an upper surface (that is located higher than the quartz crystal element 5) of the first frame portion 23ba, as with the connection electrodes 31 in the third embodiment.

The temperature sensor element (407 and the like) that functions as the lid for sealing the recess in the fourth embodiment is not limited to ones being electrically connected the mount base (in another viewpoint, terminals 3). For example, element terminals may be provided on an upper surface of a temperature sensor element (a surface opposite to the recess), and the element terminals may be electrically connected with bonding wires to a circuit substrate 53 on which the piezoelectric device is mounted.

When it is mentioned that a temperature sensor element hermetically seals a recess, the temperature sensor element may be one departing from the concept of a chip element (see the fourth embodiment). For example, a temperature sensor element including a lid and a temperature sensor film may be formed by providing a temperature sensor film (for example, a thin film thermistor) on a surface on the mount-base side of a lid that is the same as or similar to the lid of a conventional piezoelectric device as in the first embodiment.

The description of the embodiments focused attention particularly on the advantageous effect that locating the temperature sensor element on the side of the piezoelectric element opposite to the bottom surface of the recess reduces the effect that the temperature on the bottom surface side of the recess exerts on the measured temperature, so that the measured temperature is likely to follow the temperature of the piezoelectric element. However, such an advantageous effect is not essential. Even if there is not such an advantageous effect, the temperature sensor element located closer to the upper end of the recess than the piezoelectric element can provide various advantageous effects. For example, it improves the degree of freedom of design (it enables a device to include various techniques). The fourth embodiment (and the first embodiment) enables the temperature sensor element to serves also as the lid, which enables downsizing of the piezoelectric device. The first and fourth embodiments reduce the effects that an inspection or a process after the piezoelectric element is mounted on the mount base and before the recess is closed exerts on the temperature sensor element.

The following concepts can be extracted from the present disclosure.

### Concept 1

A piezoelectric device including:
a piezoelectric element;
a mount base including a recess configured to be hermetically sealed, the recess including a bottom surface on which the piezoelectric element is mounted; and
a temperature sensor element including a portion located closer to an upper end of the recess than the piezoelectric element.

### Concept 2

The piezoelectric device according to concept 1, further including
a lid closing the recess.

### Concept 3

The piezoelectric device according to concept 2, in which
the temperature sensor element includes a temperature sensor film stacked on a surface of the lid on a mount-base side.

### Concept 4

The piezoelectric device according to concept 3, in which
the temperature sensor film includes a portion overlapping the recess in transparent plan view.

### Concept 5

The piezoelectric device according to concept 3 or 4, in which
the temperature sensor film includes a portion outside the recess in transparent plan view.

### Concept 6

The piezoelectric device according to concept 2, in which
the temperature sensor element is a chip element mounted on a surface of the lid on a mount-base side.

### Concept 7

The piezoelectric device according to concept 2, in which
the temperature sensor element is a chip element mounted at a wall portion of the recess.

### Concept 8

The piezoelectric device according to concept 1, in which
the recess is hermetically sealed by the temperature sensor element.

### Concept 9

The piezoelectric device according to concept 8, in which
the temperature sensor element is a chip element.

### Concept 10

The piezoelectric device according to concept 8 or 9, in which
the temperature sensor element is not in contact with the mount base in directions parallel to the bottom surface of the recess.

### Concept 11

The piezoelectric device according to concept 8 or 9, in which
the temperature sensor element includes a portion fitted into the upper end of the recess.

### Concept 12

The piezoelectric device according to concept 8 or 9, in which
the temperature sensor element includes a portion surrounding an outer peripheral side of an upper end of the mount base.

### Concept 13

The piezoelectric device according to any one of concepts 8 to 12, in which
the temperature sensor element includes:
   an element body; and
   two element terminals exposed outside the element body,
the mount base includes:
   a substrate portion including the bottom surface of the recess;
   a frame portion including an inner peripheral surface of the recess; and
   two connection electrodes located on an upper end of the frame portion and joined to the two element terminals,
the element body is joined to the upper end of the frame portion in a sealing region extending annularly along the upper end of the frame portion, and
at least one of the two connection electrodes is located on an inner peripheral side of the sealing region.

### Concept 14

The piezoelectric device according to any one of concepts 8 to 13, in which
the temperature sensor element includes:
   an element body; and
   two element terminals exposed outside the element body,
the mount base includes:
   a substrate portion including the bottom surface of the recess;
   a frame portion including an inner peripheral surface of the recess; and
   two connection electrodes located on an upper end of the frame portion and joined to the two element terminals,
the element body is joined to the upper end of the frame portion in a sealing region extending annularly along the upper end of the frame portion, and
at least one of the two connection electrodes is located on an outer peripheral side of the sealing region.

### Concept 15

The piezoelectric device according to any one of concepts 8 to 14, in which
the temperature sensor element includes:
   an element body; and
   two element terminals exposed outside the element body,
the mount base includes:
   a substrate portion including the bottom surface of the recess;
   a frame portion including an inner peripheral surface of the recess;
   two connection electrodes located on an upper end of the frame portion and joined to the two element terminals; and
   a sealing metal layer located on the upper end of the frame portion, having an annular shape extending along the upper end of the frame portion, and joined to the element body, and
one of the two connection electrodes is connected to the metal layer, on the upper end of the frame portion.

### REFERENCE SIGNS

1 quartz crystal resonator (piezoelectric device)
5 quartz crystal element (piezoelectric element)
7 temperature sensor element
11 mount base
13 lid
R1 recess

1. A piezoelectric device comprising:
a piezoelectric element;
a mount base comprising a recess configured to be hermetically sealed, the recess comprising a bottom surface on which the piezoelectric element is mounted; and
a temperature sensor element comprising a portion located closer to an upper end of the recess than the piezoelectric element.

2. The piezoelectric device according to claim 1, further comprising
a lid closing the recess.

3. The piezoelectric device according to claim 2, wherein
the temperature sensor element comprises a temperature sensor film stacked on a surface of the lid on a mount-base side.

4. The piezoelectric device according to claim 3, wherein
the temperature sensor film comprises a portion overlapping the recess in transparent plan view.

5. The piezoelectric device according to claim 3, wherein
the temperature sensor film comprises a portion outside the recess in transparent plan view.

6. The piezoelectric device according to claim 2, wherein
the temperature sensor element is a chip element mounted on a surface of the lid on a mount-base side.

7. The piezoelectric device according to claim 2, wherein
the temperature sensor element is a chip element mounted at a wall portion of the recess.

8. The piezoelectric device according to claim 1, wherein
the recess is hermetically sealed by the temperature sensor element.

9. The piezoelectric device according to claim 8, wherein
the temperature sensor element is a chip element.

10. The piezoelectric device according to claim 8, wherein
the temperature sensor element is not in contact with the mount base in directions parallel to the bottom surface of the recess.

11. The piezoelectric device according to claim 8, wherein
the temperature sensor element comprises a portion fitted into the upper end of the recess.

12. The piezoelectric device according to claim 8, wherein
the temperature sensor element comprises a portion surrounding an outer peripheral side of an upper end of the mount base.

13. The piezoelectric device according to claim 8, wherein
the temperature sensor element comprises:
an element body; and
two element terminals exposed outside the element body,
the mount base comprises:
a substrate portion comprising the bottom surface of the recess;
a frame portion comprising an inner peripheral surface of the recess; and
two connection electrodes located on an upper end of the frame portion and joined to the two element terminals,
the element body is joined to the upper end of the frame portion in a sealing region extending annularly along the upper end of the frame portion, and
at least one of the two connection electrodes is located on an inner peripheral side of the sealing region.

14. The piezoelectric device according to claim 8, wherein
the temperature sensor element comprises:
an element body; and
two element terminals exposed outside the element body,
the mount base comprises:
a substrate portion comprising the bottom surface of the recess;
a frame portion comprising an inner peripheral surface of the recess; and
two connection electrodes located on an upper end of the frame portion and joined to the two element terminals,
the element body is joined to the upper end of the frame portion in a sealing region extending annularly along the upper end of the frame portion, and
at least one of the two connection electrodes is located on an outer peripheral side of the sealing region.

15. The piezoelectric device according to claim 8, wherein
the temperature sensor element comprises:
an element body; and
two element terminals exposed outside the element body,
the mount base comprises:
a substrate portion comprising the bottom surface of the recess;
a frame portion comprising an inner peripheral surface of the recess;
two connection electrodes located on an upper end of the frame portion and joined to the two element terminals; and
a sealing metal layer located on the upper end of the frame portion, having an annular shape extending along the upper end of the frame portion, and joined to the element body, and
one of the two connection electrodes is connected to the metal layer, on the upper end of the frame portion.
